(19) United States
(12) Patent Application Publication
(10) Pub. No.: US 2024/0315058 A1
(43) Pub. Date: Sep. 19, 2024

(54) SEMICONDUCTOR MEMORY DEVICE

(71) Applicant: Kioxia Corporation, Tokyo (JP)

(72) Inventors: Go OIKE, Kuwana Mie (JP); Kazuharu YAMABE, Yokkaichi Mie (JP)

(21) Appl. No.: 18/595,321

(22) Filed: Mar. 4, 2024

(30) Foreign Application Priority Data
Mar. 14, 2023 (JP) 2023-039346
Feb. 19, 2024 (JP) 2024-022609

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2924/1431; H01L 2924/14511

(57) ABSTRACT

A semiconductor memory device includes a first cell chip and a second cell chip. The first cell chip includes a first stack, a first conductive layer that is used as a first source line, a second conductive layer that is electrically connected to the first conductive layer, and a plurality of first bonding pads. The second cell chip includes a second stack, a third conductive layer that is used as a second source line, a plurality of second bonding pads that are joined to the plurality of first bonding pads, respectively, and a fourth conductive layer that electrically couples the plurality of second bonding pads and is electrically connected to the third conductive layer. The second conductive layer and the fourth conductive layer are electrically connected.

### CROSS-REFERENCE TO RELATED APPLICATION(S)

This application is based upon and claims the benefit of priority from Japanese Patent Application No. 2023-039346, filed Mar. 14, 2023, and Japanese Patent Application No. 2024-022609, filed Feb. 19, 2024, the entire contents of both of which are incorporated herein by reference.

### FIELD

Embodiments described herein relate generally to a semiconductor memory device.

### BACKGROUND

A NAND flash memory in which memory cell transistors are three-dimensionally arranged is known.

### DESCRIPTION OF THE DRAWINGS

FIG. 1 is a block diagram showing a schematic configuration of a memory system of a first embodiment.

FIG. 2 is a circuit diagram showing an equivalent circuit of a semiconductor memory device of the first embodiment.

FIG. 3 is a cross-sectional view showing a cross-sectional structure of the semiconductor memory device of the first embodiment.

FIG. 4 is a plan view showing a plan-view structure of a conductive layer of an upper cell chip of the first embodiment.

FIG. 5 is a cross-sectional view of a cross-section taken along the line V-V of FIG. 4.

FIG. 6 is a plan view showing a plan-view structure of a conductive layer of a lower cell chip of the first embodiment.

FIG. 7 is a plan view showing a plan-view structure of another conductive layer of the lower cell chip of the first embodiment.

FIG. 8 is a plan view showing a plan-view structure of the lower cell chip of the first embodiment.

FIG. 9 is a cross-sectional view of a cross-section taken along the line IX-IX of FIG. 8.

FIG. 10 is a plan view showing an enlarged plan-view structure of the lower cell chip of the first embodiment.

FIGS. 11-20 are cross-sectionals view showing steps of a manufacturing process of the semiconductor memory device of the first embodiment.

FIG. 21 is a cross-sectional view showing a cross-sectional structure of a semiconductor memory device of a comparative example.

FIG. 22 is a plan view showing a plan-view structure of the periphery of a conductive layer of a lower cell chip in a semiconductor memory device of a first modification example of the first embodiment.

FIG. 23 is a cross-sectional view of a cross-section taken along the line XXIII-XXIII of FIG. 22.

FIG. 24 is a plan view showing a plan-view structure of a lower cell chip of a second modification example of the first embodiment.

FIG. 25 is a plan view showing a plan-view structure of a lower cell chip of a second embodiment.

FIG. 26 is a plan view showing an enlarged plan-view structure of the lower cell chip of the second embodiment.

FIG. 27 is a cross-sectional view showing a cross-section taken along the line XXVII-XXVII of FIG. 26.

FIG. 28 is a plan view showing a plan-view structure of the periphery of a conductive layer of a lower cell chip of a modification example of the second embodiment.

FIG. 29 is a plan view showing a plan-view structure of a lower cell chip of a third embodiment.

FIG. 30 is a plan view showing an enlarged plan-view structure of the lower cell chip of the third embodiment.

FIG. 31 is a plan view of a plan-view structure of the periphery of a conductive layer of a lower cell chip of a modification example of the third embodiment.

FIG. 32 is a cross-sectional view showing a cross-sectional structure of a semiconductor memory device of a fourth embodiment.

FIG. 33 is a plan view showing a plan-view structure of a lower cell chip of the fourth embodiment.

FIG. 34 is a plan view showing an enlarged plan-view structure of the lower cell chip of the fourth embodiment.

FIG. 35 is a plan view showing a plan-view structure of the periphery of a conductive layer of a lower cell chip of a modification example of the fourth embodiment.

FIG. 36 is a cross-sectional view showing a cross-sectional structure of a semiconductor memory device of a fifth embodiment.

FIG. 37 is a cross-sectional view showing a cross-sectional structure of a semiconductor memory device of a sixth embodiment.

### DETAILED DESCRIPTION

Embodiments provide a semiconductor memory device in which sheet resistance of source lines of different cell chips in the semiconductor memory device can be made uniform more easily.

In general, according to one embodiment, a semiconductor memory device includes a substrate, a first cell chip that is provided on a first direction side of the substrate, and a second cell chip that is provided between the first cell chip and the substrate and is bonded to the first cell chip. The first cell chip includes a first stack including a plurality of first memory cell transistors, a first conductive layer that is provided on the first direction side of the first stack and is used as a first source line, a second conductive layer that is provided on the first direction side of the first conductive layer and is electrically connected to the first conductive layer, and a plurality of first bonding pads that are provided on a first surface of the first cell chip at which the first cell chip is bonded to the second cell chip. The second cell chip includes a second stack including a plurality of second memory cell transistors, a third conductive layer that is provided on the first direction side of the second stack and is used as a second source line, a plurality of second bonding pads that are disposed on a second surface of the second cell chip at which the second cell chip is bonded to the first cell chip, and are joined to the plurality of first bonding pads, respectively, and a fourth conductive layer that extends in a second direction intersecting the first direction, couples a plurality of second bonding pads, and is electrically connected to the third conductive layer. The second conductive layer and the fourth conductive layer are electrically connected.

Hereinafter, embodiments will be described with reference to the drawings. To facilitate understanding of the description, the same elements are represented by the same reference numerals as much as possible in the drawings, and redundant description will be omitted.

### 1 First Embodiment

A semiconductor memory device of a first embodiment will be described. The semiconductor memory device of the embodiment is a nonvolatile memory device configured as a NAND flash memory.

### 1.1 Configuration of Semiconductor Memory Device

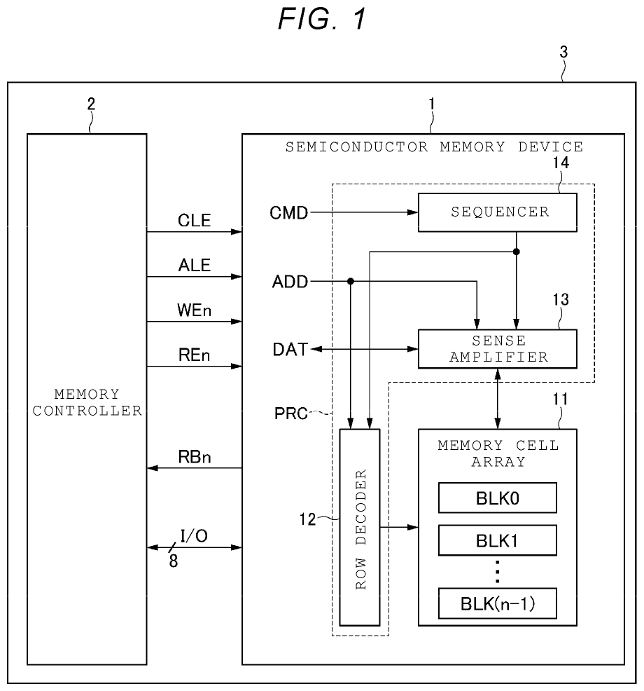

FIG. 1 is a block diagram showing an example of a configuration of a semiconductor memory device 1 of the first embodiment. The semiconductor memory device 1 is controlled by an external memory controller 2. A combination of the semiconductor memory device 1 and the memory controller 2 form a memory system 3. The memory system 3 is, for example, a memory card such as an SD™ card, a solid state drive (SSD), or the like.

The communication interface between the semiconductor memory device 1 and the memory controller 2 conforms to, for example, a NAND interface standard. In the communication interface between the semiconductor memory device 1 and the memory controller 2, for example, a command latch enable signal CLE, an address latch enable signal ALE, a write enable signal WEn, a read enable signal REn, a ready/busy signal RBn, and an input/output signal I/O are used.

The input/output signal I/O is, for example, an eight-bit signal, and may include a command CMD, address information ADD, data DAT, and the like. Hereinafter, description will be provided with a reference numeral DAT attached to both write data and read data. The semiconductor memory device 1 receives the command CMD, the address information ADD, and the write data DAT from the memory controller 2 via the input/output signal I/O.

The command latch enable signal CLE is used to notify the semiconductor memory device 1 of a period in which the command CMD is transmitted via the input/output signal I/O. The address latch enable signal ALE is used to notify the semiconductor memory device 1 of a period in which the address information ADD is transmitted via the input/output signal I/O. The write enable signal WEn is used to enable an input of the input/output signal I/O by the semiconductor memory device 1. The read enable signal REn is used to enable an output of the input/output signal I/O by the semiconductor memory device 1. The ready/busy signal RBn is used to notify the memory controller 2 of whether the semiconductor memory device 1 is in any of a ready state and a busy state. In the ready state, the semiconductor memory device 1 is capable of receiving a command from the memory controller 2. In the busy state, the semiconductor memory device 1 is not capable of receiving a command from the memory controller 2 with exceptions.

The semiconductor memory device 1 includes a memory cell array 11 and a peripheral circuit PRC. The peripheral circuit PRC includes a row decoder 12, a sense amplifier 13, and a sequencer 14. The memory cell array 11 includes blocks BLK0 to BLK(n−1) (n is an integer equal to or greater than 1). The block BLK includes a plurality of nonvolatile memory cells associated with bit lines and word lines, and is, for example, an erase unit of data.

The sequencer 14 controls the operation of the entire semiconductor memory device 1 based on a received command CMD. For example, the sequencer 14 performs control such that the row decoder 12, the sense amplifier 13, and the like execute various operations such as a write operation and a read operation. In the write operation, the received write data DAT is stored in the memory cell array 11. In the read operation, read data DAT is read from the memory cell array 11.

The row decoder 12 selects a predetermined block BLK to be subjected to various operations such as the read operation and the write operation based on the received address information ADD. The row decoder 12 transfers a voltage to word lines of the selected block BLK.

The sense amplifier 13 executes a transfer operation of data DAT between the memory controller 2 and the memory cell array 11 based on the received address information ADD. That is, the sense amplifier 13 stores the received write data DAT and applies a voltage to the bit line based on the write data DAT in the write operation. The sense amplifier 13 applies a voltage to the bit line to read data stored in the memory cell array 11 as the read data DAT and outputs the read data DAT to the memory controller 2 in the read operation.

### 1.2 Configuration of Memory Cell Array 11

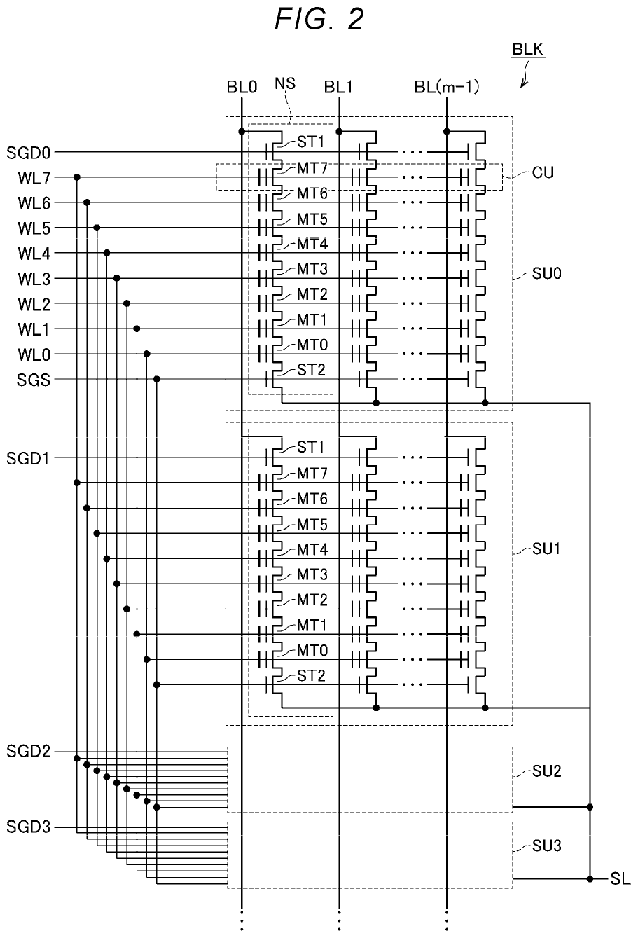

FIG. 2 shows an example of a circuit configuration of the memory cell array 11 of the semiconductor memory device 1 of the first embodiment. As the example of the circuit configuration of the memory cell array 11, an example of a circuit configuration of a predetermined block BLK of the memory cell array 11 is shown. Each of other blocks BLK of the memory cell array 11 has the same circuit configuration as, for example, that shown in FIG. 2.

The block BLK includes, for example, four string units SU0 to SU3. Each string unit SU includes a plurality of NAND strings NS. The plurality of NAND strings NS corresponds to m bit lines BL0 to BL(m−1) (m is an integer equal to or greater than 1) in a one-to-one correspondence. Each NAND string NS is connected to the corresponding bit line BL and includes, for example, memory cell transistors MT0 to MT7 and select transistors ST1 and ST2. Each memory cell transistor MT includes a control gate (hereinafter, also referred to as a gate) and a charge storage layer, and stores data in a nonvolatile manner. Each of the select transistors ST1 and ST2 is used to select the NAND string NS including the select transistors ST1 and ST2 during various operations.

A drain of the select transistor ST1 of each NAND string NS is connected to the bit line BL corresponding to the NAND string NS. The memory cell transistors MT0 to MT7 are connected in series between a source of the select transistor ST1 and a drain of the select transistor ST2. A source of the select transistor ST2 is connected to a source line SL.

Gates of the select transistors ST1 of the respective NAND strings NS in the string units SU0 to SU3 are connected in common to select gate lines SGD0 to SGD3. Gates of the select transistors ST2 of the respective NAND strings NS in the block BLK are connected in common to a select gate line SGS. Gates of the memory cell transistors MT0 to MT7 of the respective NAND strings NS in the block BLK are connected in common to word lines WL0 to WL7.

Each bit line BL is connected to the drain of the select transistor ST1 of the corresponding NAND string NS in each of the string units SU of the block BLK. The source line SL is connected in common to the sources of the select transistors ST2 of the NAND strings NS in the block BLK to be shared among the string units SU of the block BLK. The source line SL is connected similarly to, for example, different blocks BLK to be shared among the blocks BLK.

A set of memory cell transistors MT connected in common to one word line WL in one string unit SU is referred to as, for example, a cell unit CU. For example, a set of one-bit data stored in the memory cell transistors MT in the cell unit CU is referred to as “one-page data”. For example, when multi-bit data is stored in each memory cell by an MLC system or the like, a plurality of pieces of “one-page data” may be stored in one cell unit CU.

The circuit configuration of the memory cell array 11 is described, but the circuit configuration of the memory cell array 11 is not limited to that described above. For example, it is also possible to design the number of string units SU in each block BLK to be less than or greater than 4. It is possible to design the numbers of memory cell transistors MT and select transistors ST1 and ST2 in each NAND string NS to be any number. It is possible to change the numbers of word lines WL and select gate lines SGD and SGS based on the numbers of memory cell transistors MT and select transistors ST1 and ST2 in the NAND string NS.

### 1.3 Structure of Semiconductor Memory Device 1

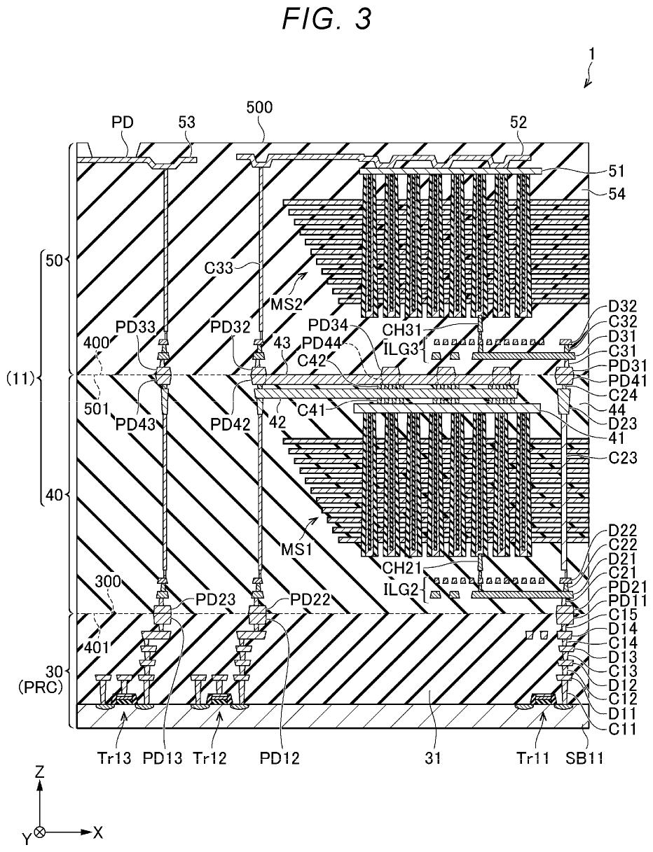

FIG. 3 shows an example of a cross-sectional structure of the semiconductor memory device 1 of the first embodiment. The semiconductor memory device 1 has a structure in which a peripheral circuit chip 30, a lower cell chip 40, and an upper cell chip 50 are bonded. A peripheral circuit PRC is provided in the peripheral circuit chip 30. A part of a memory cell array 11 is provided in each of the lower cell chip 40 and the upper cell chip 50.

Hereinafter, for convenience, directions are defined with reference to a semiconductor substrate SB11 of the peripheral circuit chip 30. For example, two perpendicular directions parallel to a predetermined surface of the semiconductor substrate SB11 are defined as an X direction and a Y direction. A direction intersecting the predetermined surface of the semiconductor substrate SB11, in which peripheral circuit elements are formed with respect to the surface, is defined as a Z direction. In the description, the Z direction is perpendicular to the X direction and the Y direction, but is not necessarily limited thereto. Hereinafter, description will be made with the Z direction as “up” and the direction opposite to the Z direction as “down”, but this notation is merely for convenience and is independent of, for example, the direction of gravity.

The peripheral circuit chip 30, the lower cell chip 40, and the upper cell chip 50 are adjacent to each other in this order along the Z direction. The semiconductor substrate SB11 of the peripheral circuit chip 30 contains, for example, silicon (Si). Metal oxide semiconductor (MOS) transistors Tr11, Tr12, and Tr13 as peripheral circuit elements in the peripheral circuit PRC are provided on an upper surface of the semiconductor substrate SB11. Each of the transistors Tr11, Tr12, and Tr13 includes a gate insulator provided on the upper surface of the semiconductor substrate SB11, a gate electrode provided on an upper surface of the gate insulator, a pair of source/drain regions, and a region of the semiconductor substrate SB11 below the gate insulator interposed between the source/drain regions.

Conductive layers D11, D12, D13, and D14 are provided above the transistors Tr11, Tr12, and Tr13. Each conductive layer includes a plurality of wires insulated from each other. It is possible to electrically connect a source, a drain, and a gate of each of the transistors Tr11, Tr12, and Tr13 to other elements. In FIG. 3, a case where four conductive layers are provided is described, but the disclosure is not necessarily limited thereto.

A contact plug C11 is provided on an upper surface of a source/drain region of the transistor Tr11. An upper surface of the contact plug C11 is joined to a predetermined wire in the conductive layer D11. A contact plug C12 is provided on an upper surface of the predetermined wire in the conductive layer D11. An upper surface of the contact plug C12 is joined to a predetermined wire in the conductive layer D12. A contact plug C13 is provided on an upper surface of the predetermined wire in the conductive layer D12. An upper surface of the contact plug C13 is joined to a predetermined wire in the conductive layer D13. A contact plug C14 is provided on an upper surface of the predetermined wire in the conductive layer D13. An upper surface of the contact plug C14 is joined to a predetermined wire in the conductive layer D14. A contact plug C15 is provided on an upper surface of the predetermined wire in the conductive layer D14. A conductive layer PD11 is provided on an upper surface of the contact plug C15.

The conductive layer PD11 contains, for example, a metal material such as copper (Cu). An upper surface of the conductive layer PD11 forms a part of an upper surface of the peripheral circuit chip 30 and is substantially at the same position as the upper surface of the peripheral circuit chip 30 in the Z direction. The conductive layer PD11 functions as an electrode pad that is used for electrical connection to another chip. Hereinafter, a conductor that is provided on the upper surface of the peripheral circuit chip 30 and functions as an electrode pad is referred to as a bonding pad PD11. Reference numeral PD is attached to the conductor that functions as an electrode pad in this way.

In addition to the bonding pad PD11, bonding pads PD12 and PD13 electrically connected to other transistors Tr12 and Tr13, respectively, are provided on the upper surface of the peripheral circuit chip 30. In the specification, for example, the contact plug C13 and the wire in the conductive layer D13 are distinguished, but the contact plug C13 and the wire in the conductive layer D13 joined to each other as shown in the drawing may be integrated. The same applies to other contact plugs and conductive layers.

The connection via the wires in the conductive layers D11, D12, D13, and D14 is merely an example. In the peripheral circuit chip 30, various contact plugs, the wires in the conductive layers D11, D12, D13, and D14, and the bonding pad PD11 as described above are provided. In FIG. 3, for convenience, all of various contact plugs, the wires in the conductive layers D11, D12, D13, and D14, and the bonding pads PD11, PD12, and PD13 are not necessarily shown.

Between the semiconductor substrate SB11 and the upper surface of the peripheral circuit chip 30, an insulating layer 31 is provided in a portion where the transistors Tr11, Tr12, and Tr13, various contact plugs, the wires in the conductive layers D11, D12, D13, and D14, and the bonding pads PD11, PD12, and PD13 are not provided. The insulating layer 31 contains, for example, oxygen and silicon (for example, SiO₂). The insulating layer 31 may further contain nitrogen or carbon.

A bottom surface 401 of the lower cell chip 40 is bonded to an upper surface 300 of the peripheral circuit chip 30. The lower cell chip 40 includes a stack MS1 that functions as a part of the memory cell array 11. More specifically, each of memory pillars in the stack MS1 functions as, for example, one NAND string NS.

Bonding pads PD21, PD22, and PD23 are provided on the bottom surface of the lower cell chip 40. The bonding pads PD21, PD22, and PD23 are joined to the upper surfaces of the respective bonding pads PD11, PD12, and PD13 of the peripheral circuit chip 30. A bottom surface of each of the bonding pads PD21, PD22, and PD23 forms a part of the bottom surface of the lower cell chip 40 and is substantially at the same position as the bottom surface of the lower cell chip 40 in the Z direction. The bonding pads PD21, PD22, and PD23 contain, for example, a metal material such as copper (Cu).

A contact plug C21 is provided on an upper surface of the bonding pad PD21. An upper surface of the contact plug C21 is joined to a predetermined wire in the conductive layer D21. A contact plug C22 is provided on an upper surface of the predetermined wire in the conductive layer D22. An upper surface of the contact plug C22 is joined to a predetermined wire in the conductive layer D22. A contact plug C23 is provided on an upper surface of the predetermined wire in the conductive layer D22. An upper surface of the contact plug C23 is joined to a predetermined wire in the conductive layer D23. A contact plug C24 is provided on an upper surface of the predetermined wire in the conductive layer D23. An upper surface of the contact plug C24 is joined to a bonding pad PD41. With such a structure, the bonding pad PD21 disposed on the bottom surface 401 of the lower cell chip 40 is electrically connected to the bonding pad PD41 disposed on an upper surface 400 of the lower cell chip 40. The bonding pad PD41 contains, for example, a metal material such as copper (Cu).

Similarly, other bonding pads PD22 and PD23 are also electrically connected to bonding pads PD42 and PD43 via the contact plugs C21, the conductive layer D21, the contact plugs C22, the conductive layer D22, the contact plugs C23, the conductive layer D23, and the contact plugs C24, respectively. The bonding pads PD42 and PD43 also contain, for example, a metal material such as copper (Cu).

In the conductive layer D21, the predetermined wire connected to the bonding pads PD21 and PD41 is electrically connected to a predetermined wire in a lowermost metal wiring layer of a metal wiring layer group ILG2. The wire is electrically connected to a predetermined wire in an uppermost metal wiring layer of the metal wiring layer group ILG2. The wire is electrically connected to a predetermined contact plug CH21 above the metal wiring layer group ILG2. Accordingly, the bonding pad PD21 is electrically connected to the contact plug CH21. An upper surface of the contact plug CH21 is in contact with a lower end of a predetermined memory pillar of the stack MS1. Of the wires in the metal wiring layer group ILG2, the wire electrically connected to the contact plug CH21 in this way functions as a part of the bit line BL.

A conductive layer 41 is provided on an upper surface of the stack MS1. The conductive layer 41 contains, for example, a semiconductor material or metal, for example, polysilicon (Si), tungsten (W) or silicon and tungsten. The conductive layer 41 spreads in a planar shape parallel to the X direction and the Y direction. The conductive layer 41 functions as a part of the source line SL. Hereinafter, the conductive layer 41 is also referred to as a source layer 41.

A plurality of contact plugs C41 are provided on an upper surface of the conductive layer 41. A conductive layer 42 is provided on upper surfaces of the contact plugs C41. The conductive layer 42 contains, for example, a metal material such as copper (Cu). The conductive layer 42 extends in the X direction. One end portion of the conductive layer 42 is electrically connected to a predetermined wire in the conductive layer D23, and specifically, a wire corresponding to the bonding pads PD22 and PD42. The conductive layer 42 functions as a backing wire of the conductive layer 41 that functions as the source line SL of the lower cell chip 40.

A plurality of contact plugs C42 are provided on an upper surface of the conductive layer 42. A plurality of bonding pads PD44 are provided on upper surfaces of the contact plugs C42.

The plurality of bonding pads PD44 are coupled to each other by a conductive layer 43. The bonding pads PD44 and the conductive layer 43 contain, for example, a conductive material such as copper (Cu). The conductive layer 43 extends in the X direction. One end portion of the conductive layer 43 is electrically connected to the bonding pad PD42. Similarly to the conductive layer 42, the conductive layer 43 functions as a backing wire of the conductive layer 41 that functions as the source line SL of the lower cell chip 40.

An upper surface of each of the bonding pads PD41, PD42, PD43, and PD44 and the conductive layer 43 forms a part of the upper surface of the lower cell chip 40 and is substantially at the same position as the upper surface of the lower cell chip 40 in the Z direction. The bonding pads PD41, PD42, PD43, and PD44 function as electrode pads that are used for electrical connection to the upper cell chip 50.

In the lower cell chip 40, an insulating layer 44 is provided in a portion where each bonding pad, each contact plug, each conductive layer, the wire of each wiring layer of the metal wiring layer group ILG2, the stack MS1, and the like are not provided. The insulating layer 44 contains, for example, oxygen and silicon (for example, SiO₂). The insulating layer 44 may further contain nitrogen or carbon.

A bottom surface 501 of the upper cell chip 50 is bonded to the upper surface 400 of the lower cell chip 40. The upper cell chip 50 has a structure similar to the lower cell chip 40. For this reason, hereinafter, description of the structure of the upper cell chip 50 will be simplified as much as possible.

The upper cell chip 50 includes a stack MS2 that functions as a part of the memory cell array 11. Bonding pads PD31, PD32, PD33, and PD34 are provided on the bottom surface 501 of the upper cell chip 50. The bonding pads PD31, PD32, PD33, and PD34 are joined to the bonding pads PD41, PD42, PD43, and PD44 of the lower cell chip 40, respectively.

The bonding pad PD31 is connected to the stack MS2 via a contact plug C31, a predetermined wire in a conductive layer D31, a metal wiring layer group ILG3, and a contact plug CH31. A conductive layer 51 is provided on an upper surface of the stack MS2. The conductive layer 51 functions as a part of the source line SL. Hereinafter, the conductive layer 51 is also referred to as a source layer 51.

A conductive layer 52 is provided on an upper surface of the conductive layer 51. The conductive layer 52 contains, for example, a conductive material such as aluminum (AL). The conductive layer 51 and the conductive layer 52 are electrically connected. The conductive layer 52 functions as a backing wire of the source line SL of the upper cell chip 50.

The bonding pad PD32 is connected to a conductive layer 52 via the contact plug C31, a predetermined wire in the conductive layer D31, a contact plug C32, a predetermined wire in a conductive layer D32, and a contact plug C33.

The bonding pad PD33 is connected to a conductive layer 53 via the contact plug C31, a predetermined wire in the conductive layer D31, the contact plug C32, a predetermined wire in the conductive layer D32, and the contact plug C33. The conductive layer 53 contains, for example, aluminum (AL).

In the upper cell chip 50, an insulating layer 54 is provided in a portion where each bonding pad, each contact plug, each conductive layer, the wire in each wiring layer of the metal wiring layer group ILG3, the stack MS2, and the like are not provided. The insulating layer 54 contains, for example, oxygen and silicon (for example, SiO₂). The insulating layer 54 may further contain nitrogen or carbon. A part of the conductive layer 53 is exposed to the outside from the insulating layer 54 to function as an electrode pad PD. The electrode pad PD is a portion connectable to a mounting substrate, external equipment, or the like by a bonding wire, a solder ball, a metal bump, or the like.

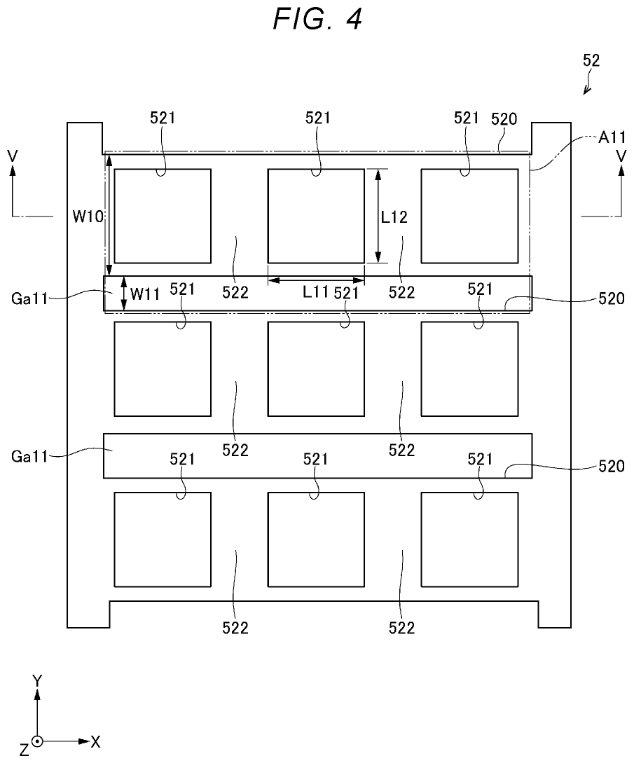

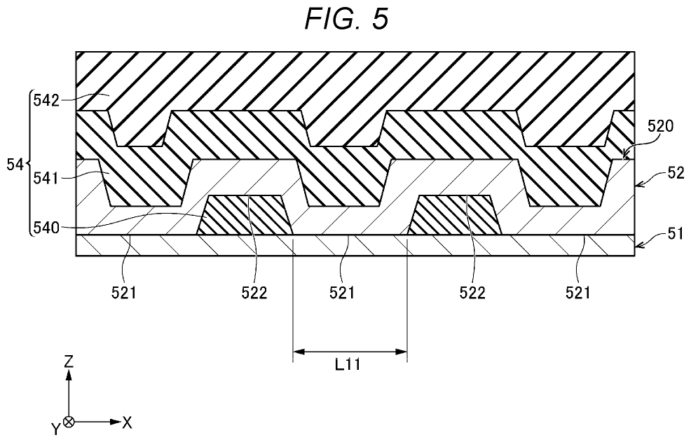

Next, the structure of the conductive layer 52 of the upper cell chip 50 will be described in detail. FIG. 4 shows a part of a plan-view structure of the conductive layer 52. FIG. 5 shows a cross-sectional structure taken along the line V-V of FIG. 4.

As shown in FIG. 4, a plurality of wires 520 that extend in the X direction are formed in the conductive layer 52. In the upper cell chip 50, the plurality of wires 520 are disposed in parallel at predetermined gaps Gall in the Y direction. In each wire 520, a plurality of contact portions 521 are formed at predetermined intervals in the X direction. When viewed from the Z direction, the contact portions 521 are formed in a rectangular shape. As shown in FIG. 5, the contact portion 521 is recessed in a recess shape toward the source layer 51. Because a bottom surface of the contact portion 521 is in contact with an upper surface of the source layer 51, the source layer 51 and the conductive layer 52 are electrically connected.

As shown in FIG. 4, a width W10 of the wire 520 in the Y direction is set to, for example, 4 μm, and a width W11 of the gap Gall in the Y direction is set to, for example, 1.5 μm. Lengths L11 and L12 of the contact portion 521 in the X direction and the Y direction viewed from the Z direction are set to, for example, 3.5 μm.

As shown in FIG. 5, an insulating layer 540 that forms a part of the insulating layer 54 is provided between portions 522 excluding the contact portion 521 in the wire 520 and the source layer 51. The insulating layer 540 contains, for example, oxygen and silicon (for example, SiO₂). Accordingly, portions 522 are portions not in contact with the source layer 51. Hereinafter, the portions 522 are also referred to as non-contact portions 522.

An insulating layer 541 and an insulating layer 542 that each form a part of the insulating layer 54 are stacked in order on an upper surface of the wire 520. The insulating layer 541 contains, for example, nitrogen and silicon. The insulating layer 542 contains, for example, polyimide.

As shown in FIG. 4, in the upper cell chip 50, an aperture ratio of a region A11 surrounded by a two-dot chain line, that is, the rectangular region A11 including the wire 520 and the gap Gall is 30% to 40%. The aperture ratio of the region A11 indicates a ratio of an area occupied by a region where the wire 520 is not disposed, to a total area of the region A11 viewed from the Z direction in percentage.

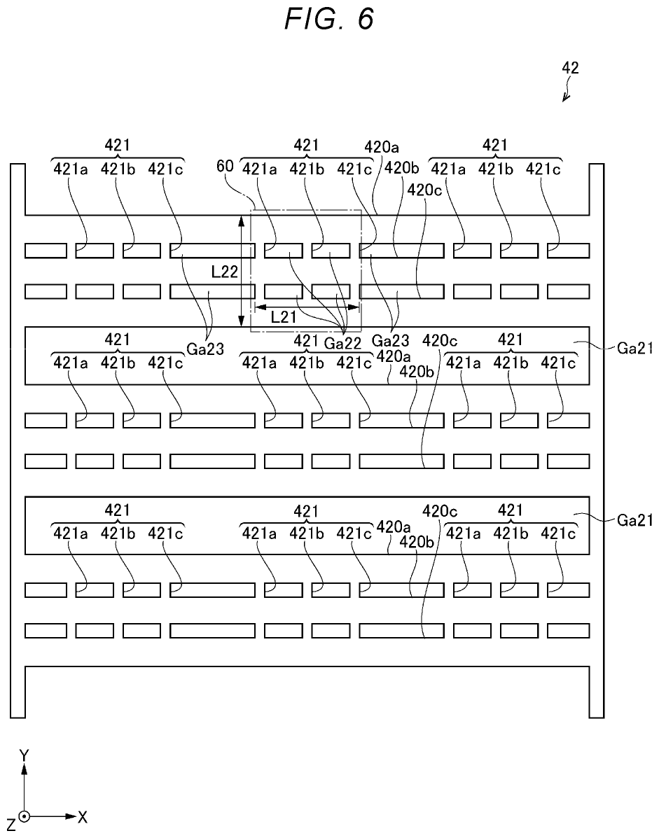

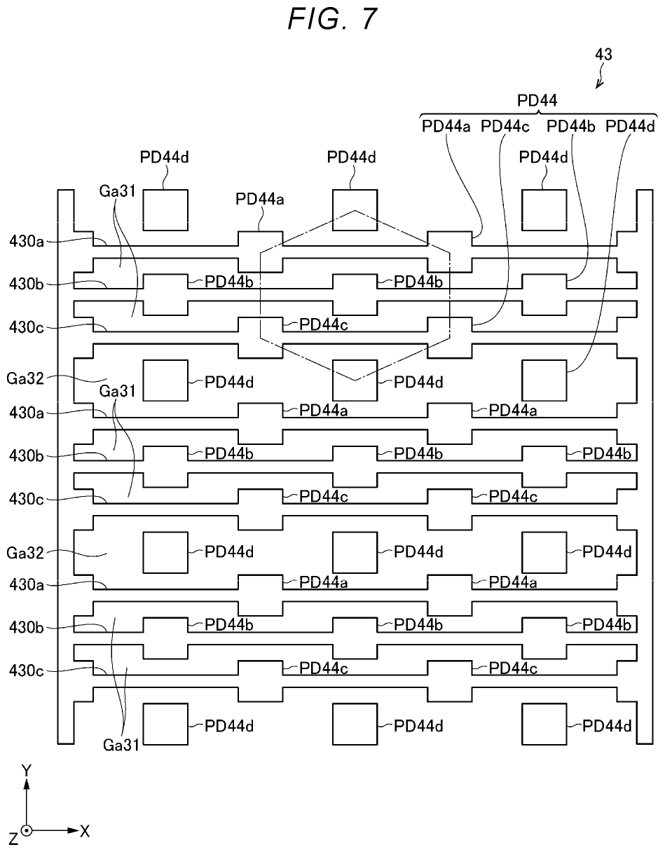

Next, the conductive layers 42 and 43 of the lower cell chip 40 will be described in detail. FIG. 6 shows a plan-view structure of the conductive layer 42. FIG. 7 shows a plan-view structure of the conductive layer 43.

As shown in FIG. 6, in the conductive layer 42, with three wires 420a to 420c extending in the X direction as a set, a plurality of sets of wires 420a to 420c are disposed in parallel at predetermined gaps Ga21 in the Y direction.

In the conductive layer 42, a plurality of bridging portions 421 that couple the wires 420a to 420c in the Y direction are further provided. Each bridging portion 421 includes three bridging wires 421a to 421c that are disposed at gaps Ga22 in the X direction. Three bridging portions 421 each of which includes the three bridging wires 421a to 421c are disposed in parallel in the X direction at gaps Ga23 greater than the gaps Ga22. A portion in the conductive layer 42 where one bridging portion 421 is provided, that is, a portion 60 indicated by a one-dot chain line in FIG. 6 is formed in a substantially rectangular shape similar to the shape of the contact portion 521 of the conductive layer 52 shown in FIG. 4. Hereinafter, the portion is referred to as a simulated shape portion 60. Lengths L21 and L22 of the simulated shape portion 60 in the X direction and the Y direction are set to, for example, 3 μm. That is, when viewed from the Z direction, the size of the portion 60 is slightly smaller than the size of the contact portion 521 shown in FIG. 4.

As shown in FIG. 7, in the conductive layer 43, with three wires 430a to 430c extending in the X direction as a set, the wires 430a to 430c are disposed in parallel at predetermined gaps Ga31 in the Y direction. The sets of the three wires 430a to 430c are disposed in parallel at predetermined gaps Ga32 in the Y direction. Each of the wires 430a to 430c passes through a plurality of bonding pads PD44 in the X direction.

In detail, a plurality of bonding pads PD44 are disposed in a zigzag pattern when viewed from the Z direction. As indicated by a one-dot chain line in the drawing, the plurality of bonding pads PD44 are disposed at positions where lines that connect the geometric centers of the bonding pads PD44 become a honeycomb shape. Each of the wires 430a to 430c passes through a plurality of bonding pads PD44 that are disposed in a line in the X direction. Hereinafter, of the plurality of bonding pads PD44, the bonding pads disposed on the wire 430a are referred to as bonding pads PD44a, the bonding pads disposed on the wire 430b are referred to as bonding pads PD44b, and the bonding pads disposed on the wire 430c are referred to as bonding pads PD44c.

The bonding pads PD44 arranged in a line in the X direction are also disposed in the gaps Ga32 formed between the wires 430a and the wires 430c. Hereinafter, the bonding pads PD44, that is, the bonding pads that are disposed in the gaps Ga32 and are not electrically connected to any of the wires 430a to 430c are referred to as bonding pads PD44d.

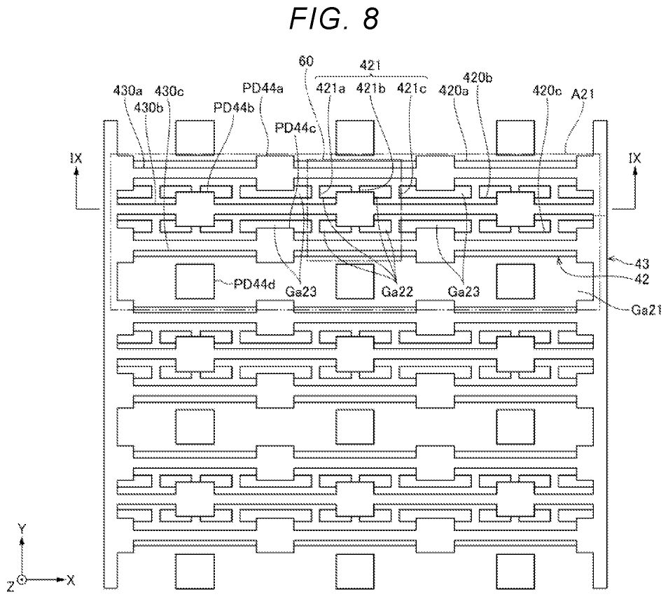

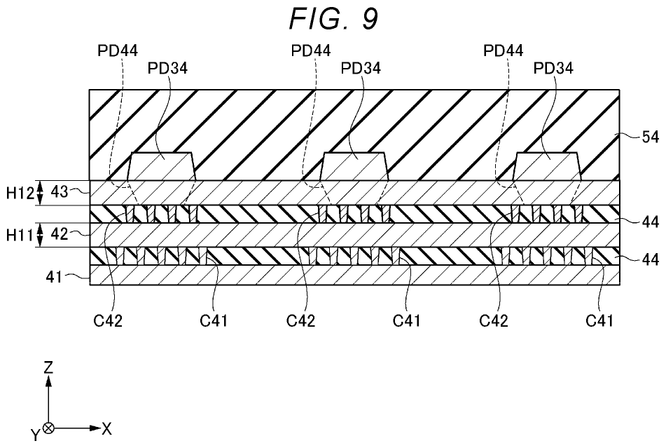

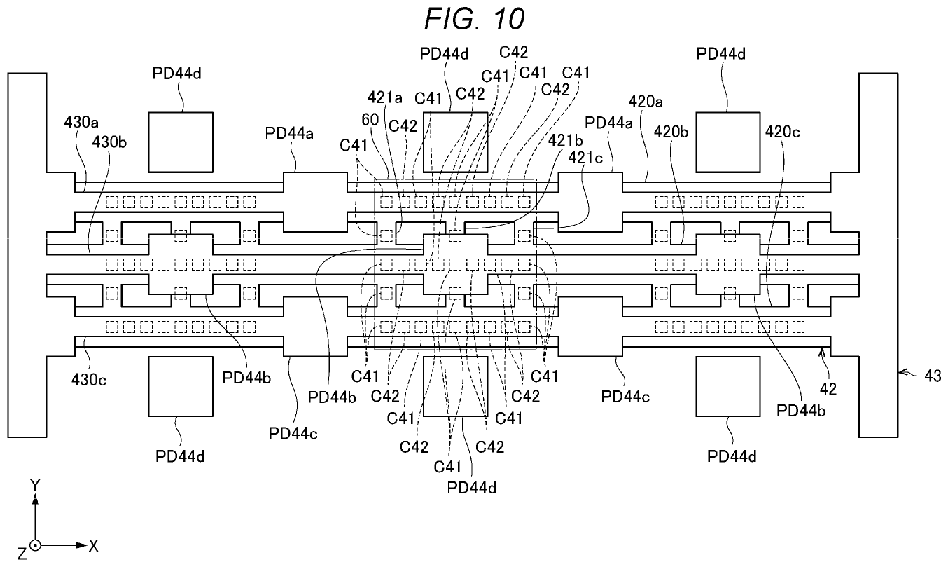

FIG. 8 shows a plan-view structure of the lower cell chip 40. FIG. 9 shows a cross-sectional structure taken along the line IX-IX of FIG. 8. FIG. 10 shows an enlarged plan-view structure of a region A21 of FIG. 8. In FIG. 8, the insulating layer 44 is not shown.

As shown in FIG. 9, a bottom surface of the conductive layer 42 is electrically connected to the source layer 41 via a plurality of contact plugs C41 in the Z direction. The contact plugs C41 are formed using, for example, tungsten (W) or copper (Cu). As shown in FIG. 10, the contact plugs C41 are disposed along the wires 420a to 420c and the bridging wires 421a to 421c of the conductive layer 42. More specifically, the contact plugs C41 are disposed at predetermined intervals in the X direction with respect to portions in the respective wires 420a to 420c positioned within the region of the simulated shape portion 60. The contact plugs C41 are disposed at predetermined intervals in the Y direction also with respect to the bridging wires 421a to 421c.

As shown in FIG. 9, a bottom surface of the conductive layer 43 is electrically connected to the upper surface of the conductive layer 42 via a plurality of contact plugs C42 in the Z direction. The contact plugs C42 are formed using, for example, tungsten (W) or copper (Cu). As shown in FIG. 10, the contact plugs C42 are disposed along the wires 430a to 430c of the conductive layer 43. More specifically, the contact plugs C42 are disposed in parallel at predetermined intervals in the X direction to be positioned between adjacent the contact plugs C41 in portions in the wires 430a to 430c positioned within the region of the simulated shape portion 60. With such a structure, the wires 430a to 430c of the conductive layer 43, the bonding pads PD44a to PD44c, and the bonding pads PD34 of the upper cell chip 50 joined to the bonding pads PD44a to PD44c are electrically connected to the source layer 41 via the contact plugs C42, the conductive layer 42, and the contact plugs C41 and function as a backing wire of the source layer 41.

Meanwhile, the bonding pads PD44d of the conductive layer 43 and the bonding pads PD34 of the upper cell chip 50 joined to the bonding pads PD44d become so-called dummy pads that do not have a function as a wire.

A thickness H11 of the conductive layer 42 in the Z direction shown in FIG. 9 is set to about 250 to 450 nm. A thickness H12 of the conductive layer 43 in the Z direction is set to about 250 to 450 nm similarly to the conductive layer 42.

As shown in FIG. 8, in the lower cell chip 40, an aperture ratio of the region A21 surrounded by the two-dot chain line, that is, the rectangular region A21 including the wires 420a to 420c, the bridging wires 421a to 421c, the wires 430a to 430c, the bonding pads PD44a to PD44d, and the gaps Ga21, Ga22, and Ga23 is 35% to 45%. The aperture ratio of the region A21 indicates a ratio of an area occupied by a region where the wires 420a to 420c, the bridging wires 421a to 421c, the wires 430a to 430c, and the bonding pads PD44a to PD44d are not disposed, with respect to a total area of the region A21 viewed from the Z direction in percentage.

### 1.4 Manufacturing Method for Semiconductor Memory Device 1

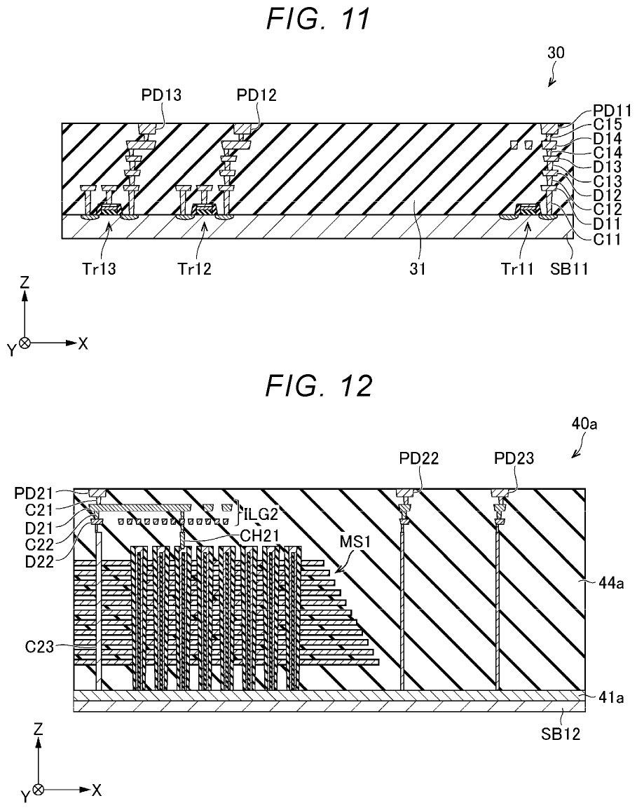

Next, a manufacturing method for the semiconductor memory device 1 will be described. In manufacturing the semiconductor memory device 1, first, the peripheral circuit chip 30 shown in FIG. 11 is manufactured.

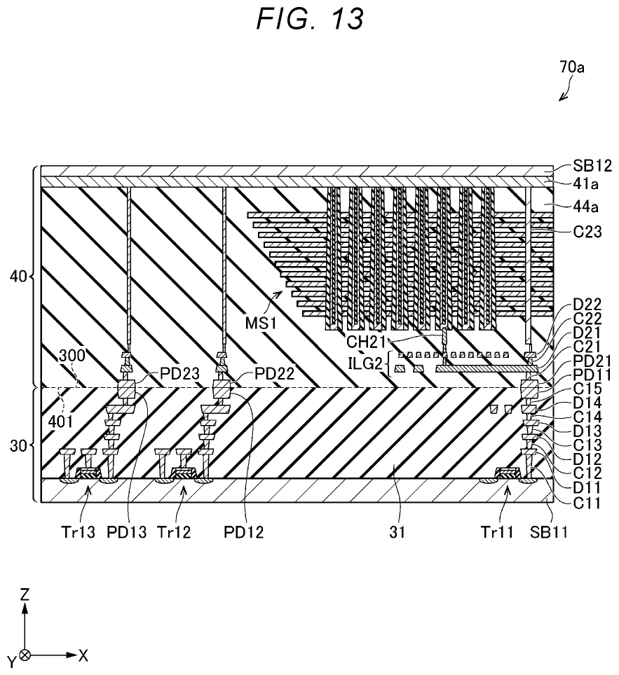

Next, a shaped product 40a shown in FIG. 12 is manufactured. In manufacturing the shaped product 40a shown in FIG. 12, first, a conductive layer 41a is formed on an upper surface of a semiconductor substrate SB12. The semiconductor substrate SB12 contains, for example, silicon (Si). Silicon contains, for example, a P-type impurity. An insulating film of, for example, an oxide film (not shown) of silicon is provided on the upper surface of the semiconductor substrate SB12. The conductive layer 41a contains, for example, a semiconductor material, and contains, for example, polysilicon (Si). Thereafter, the stack MS1 and an insulating layer 44a are formed on an upper surface of the conductive layer 41a. The insulating layer 44a contains, for example, oxygen and silicon (for example, SiO₂). Next, the contact plugs C23 and CH21, the conductive layer D22, the metal wiring layer group ILG2, the contact plugs C22, the conductive layer D21, the contact plugs C21, and the bonding pads PD21, PD22, and PD23 are formed by anisotropic etching such as a reactive ion etching (RIE) method, a damascene process, and the like, so that the shaped product 40a is formed.

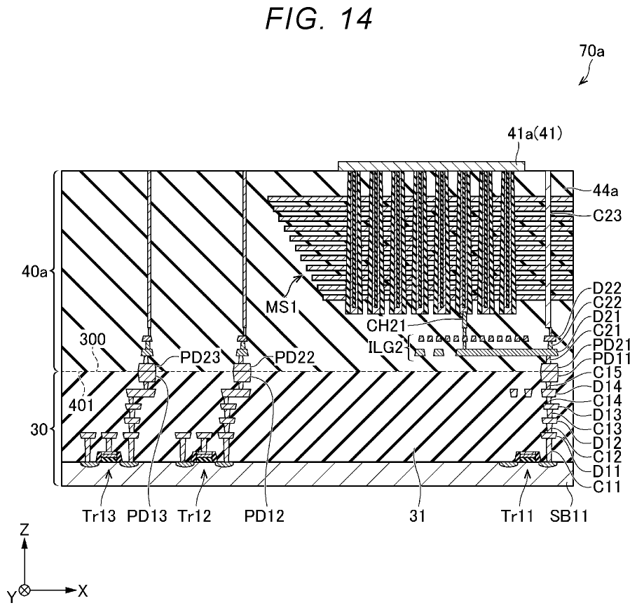

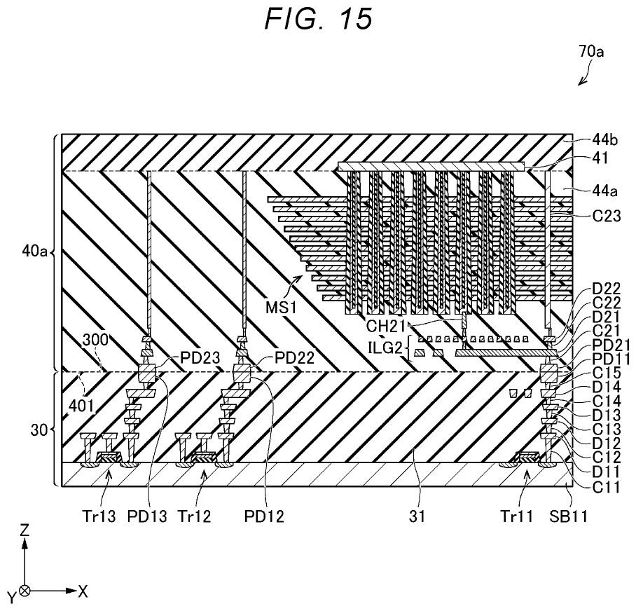

Subsequently, an upper surface of the shaped product 40a shown in FIG. 12 is bonded to an upper surface of the peripheral circuit chip 30 shown in FIG. 11, so that a bonded product 70a as shown in FIG. 13 is formed. In the bonded product 70a, the shaped product 40a shown in FIG. 12 is upside down. On the bonded product 70a, as shown in FIG. 14, a silicon portion of the semiconductor substrate SB12 is removed by, for example, chemical mechanical polishing (CMP). After the silicon portion of the semiconductor substrate SB12 is removed, an insulating film portion of the semiconductor substrate SB12 and a part of the conductive layer 41a are removed. With this, the conductive layer 41 that functions as the source line SL is formed. Subsequently, as shown in FIG. 15, an insulating layer is formed above the conductive layer 41. In FIG. 15, the insulating layer formed in this way is represented by reference numeral 44b. The insulating layer 44b contains, for example, oxygen and silicon (for example, SiO₂).

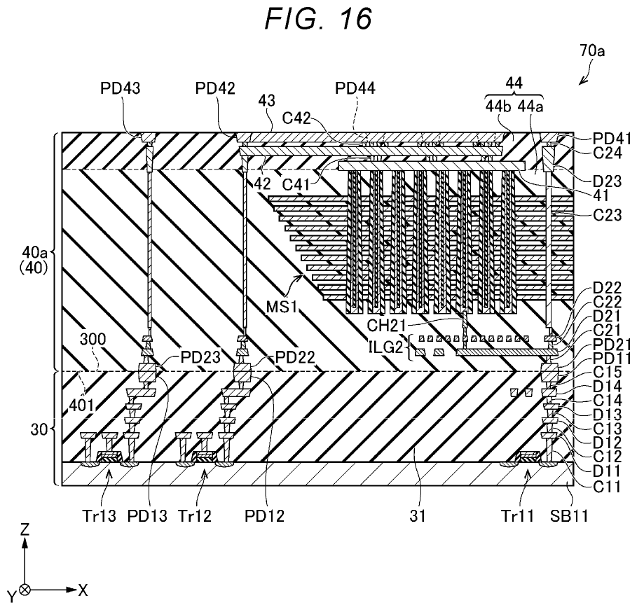

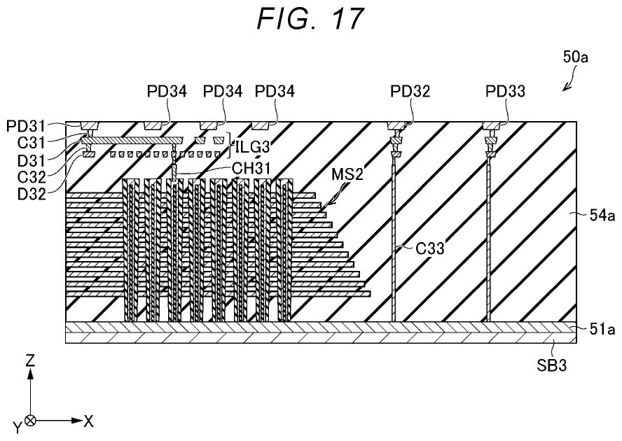

Next, as shown in FIG. 16, the contact plugs C41, the conductive layer 42, the contact plugs C42, the bonding pads PD44, and the conductive layer 43 are formed on an upper surface of the conductive layer 41 by anisotropic etching such as an RIE method, a damascene process, and the like. The conductive layer D23, the contact plugs C24, and the bonding pads PD41, PD42, and PD43 are formed on upper surfaces of the contact plugs C23. With the above process, the bonded product 70a shown in FIG. 16 is formed. In the bonded product 70a, a combination of the insulating layer 44a and the insulating layer 44b corresponds to the insulating layer 44 shown in FIG. 3. A structure that is bonded above the peripheral circuit chip 30 corresponds to the lower cell chip 40 shown in FIG. 3.

Next, a shaped product 50a shown in FIG. 17 is manufactured. In manufacturing the shaped product 50a shown in FIG. 17, first, a conductive layer 51a is formed on an upper surface of a semiconductor substrate SB3. The semiconductor substrate SB3 contains, for example, silicon (Si). Silicon contains, for example, a P-type impurity. An insulating film (not shown) of, for example, an oxide film of silicon is provided on the upper surface of the semiconductor substrate SB3. The conductive layer 51a contains, for example, a semiconductor material, and contains, for example, polysilicon (Si). Thereafter, the stack MS2 and an insulating layer 54a are formed on an upper surface of the conductive layer 51a. The insulating layer 54a contains, for example, oxygen and silicon (for example, SiO₂). Next, the contact plugs C33 and CH31, the conductive layer D32, the metal wiring layer group ILG3, the contact plugs C32, the conductive layer D31, the contact plugs C31, and the bonding pads PD31, PD32, PD33, and PD34 are formed by anisotropic etching such as an RIE method, a damascene process, and the like, so that the shaped product 50a is formed.

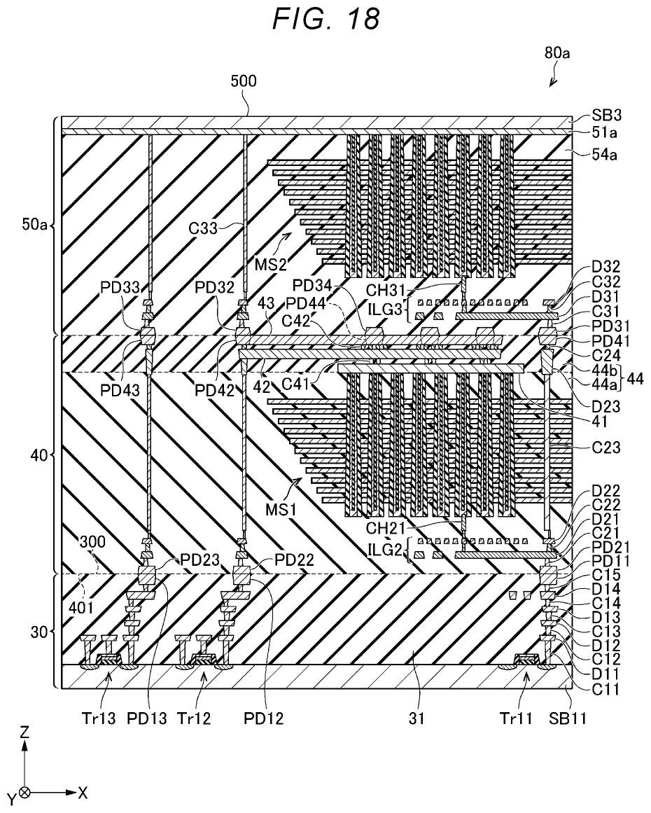

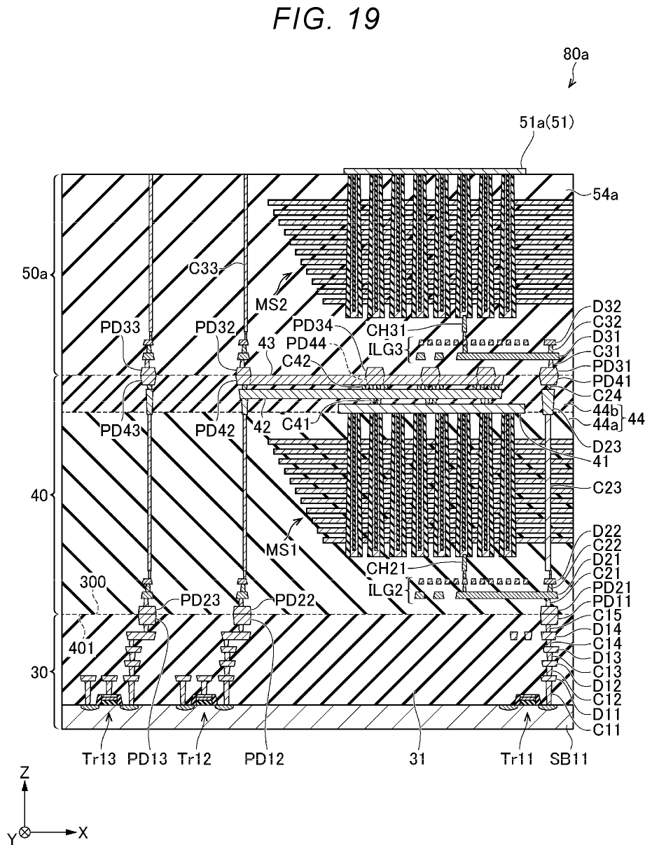

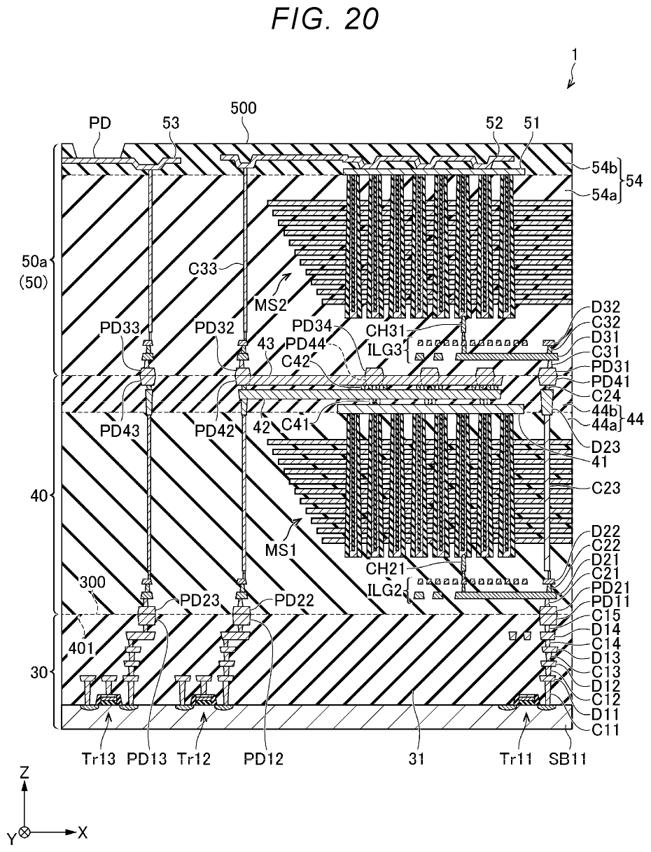

Subsequently, an upper surface of a shaped product 50a shown in FIG. 17 is bonded to an upper surface of the bonded product 70a shown in FIG. 16, so that a bonded product 80a as shown in FIG. 18 is formed. In the bonded product 80a, the shaped product 50a shown in FIG. 17 is upside down. The same processing as the processing on the upper surface of the bonded product 70a shown in FIGS. 14 and 15 is performed on an upper surface of the bonded product 80a shown in FIG. 18, so that the semiconductor substrate SB3 and a part of the conductive layer 51a are removed. With this, as shown in FIG. 19, the conductive layer 51 that functions as the source line SL is formed. Subsequently, as shown in FIG. 20, the conductive layers 52 and 53 and an insulating layer 54b are formed. The insulating layer 54b includes the insulating layer 541 and the insulating layer 542. The insulating layer 54b contains, for example, oxygen and silicon (for example, SiO₂). In the bonded product 80a, a combination of the insulating layer 54a and the insulating layer 54b corresponds to the insulating layer 54 shown in FIG. 3. A structure that is bonded above the lower cell chip 40 corresponds to the upper cell chip 50 shown in FIG. 3. With the above, the semiconductor memory device 1 shown in FIG. 3 is manufactured.

### 1.5 Functions and Effects

In the semiconductor memory device 1 of the embodiment, the upper cell chip 50 includes the stack MS2, the conductive layers 51 and 52, and the bonding pads PD34. The stack MS2 functions as a part of the memory cell array 11 including a plurality of memory cell transistors MT. The conductive layer 51 is provided above the stack MS2 and is used as the source line SL. The conductive layer 52 is provided above the conductive layer 51 and is bonded to the conductive layer 51. The bonding pads PD34 are disposed on the bottom surface 501 that is a bonding surface to the lower cell chip 40.

The lower cell chip 40 includes the stack MS1, the conductive layers 41 to 43, and the bonding pads PD44. The stack MS1 functions as a part of the memory cell array 11 including a plurality of memory cell transistors MT. The conductive layer 41 is provided above the stack MS1 and is used as the source line SL. The bonding pads PD44 are disposed on the upper surface 400 that is a bonding surface to the upper cell chip 50, and are joined to a plurality of bonding pads PD34, respectively. The conductive layer 43 extends in the X direction, couples a plurality of bonding pads PD44, and is electrically connected to the conductive layer 41.

Specifically, the lower cell chip 40 further includes the conductive layer 42 that is provided between the conductive layer 41 and the conductive layer 43, the contact plugs C41 that electrically connect the conductive layer 41 and the conductive layer 42, and the contact plugs C42 that electrically connect the conductive layer 42 and the conductive layer 43. The conductive layer 52 and the conductive layer 43 are electrically connected.

According to the above-described configuration, in the upper cell chip 50, the conductive layer 52 functions as a backing wire with respect to the conductive layer 51 that is used as the source line SL. Accordingly, in the upper cell chip 50, the sheet resistance of the source line SL is determined by the resistance of the conductive layer 52. In contrast, in the lower cell chip 40, the conductive layers 42 and 43 function as a backing wire with respect to the conductive layer 41 that is used as the source line SL. Accordingly, in the lower cell chip 40, the sheet resistance of the source line SL is determined by the resistance of the conductive layers 42 and 43 and a plurality of bonding pads PD44 coupled to the conductive layer 43.

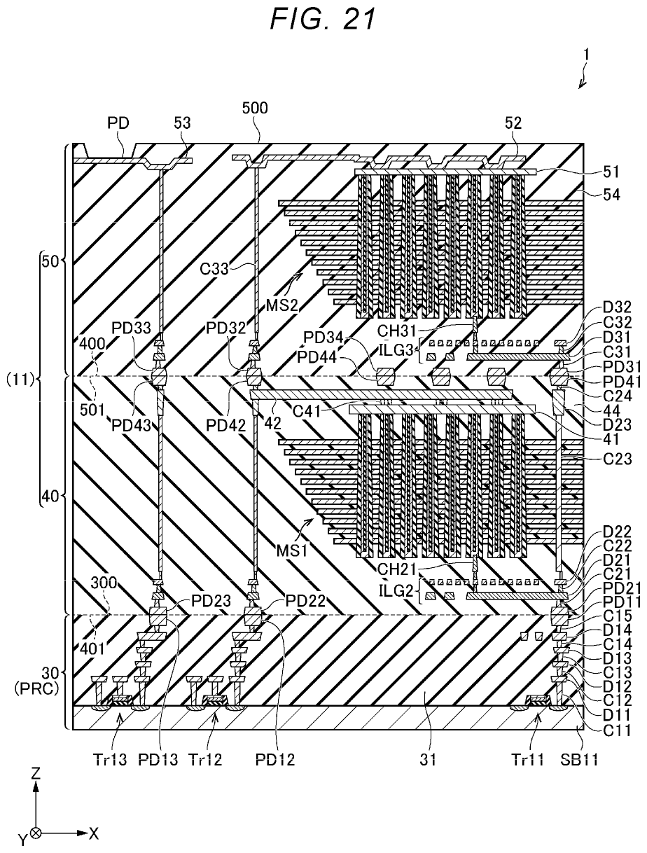

Conversely, in a semiconductor memory device 100 of a comparative example shown in FIG. 21, for example, only the conductive layer 42 is connected to the conductive layer 41, and thus only the conductive layer 42 is used as a backing wire of the source line SL in the lower cell chip 40. As described above, while the conductive layer 52 of the upper cell chip 50 contains aluminum, the conductive layer 42 of the lower cell chip 40 contains copper. For this reason, for example, when only the conductive layer 42 is used as a backing wire of the source line SL in the lower cell chip 40, due to a difference between the materials of the conductive layer 52 of the upper cell chip 50 and the conductive layer 42 of the lower cell chip 40, it is difficult to match the sheet resistances of the source lines SL of the respective cell chips 40 and 50.

In the lower cell chip 40 of the embodiment, as described above, because the sheet resistance of the source line SL is determined by the resistance of the conductive layers 42 and 43 and a plurality of bonding pads PD44 coupled to the conductive layer 43, it is possible to make the sheet resistance close to the sheet resistance of the source line SL of the upper cell chip 50. Therefore, the sheet resistance of the source line SL of each of the cell chips 40 and 50 is made uniform more easily.

In the semiconductor memory device 1 of the embodiment, the conductive layer 52 of the upper cell chip 50 has the contact portions 521 that are joined to the conductive layer 51, and non-contact portions 522 that are not joined to the conductive layer 51 with the insulating layer 540 interposed therebetween. The simulated shape portion 60 of the conductive layer 42 that overlaps the contact portion 521 when viewed from the Z direction is formed in a rectangular shape similar to the contact portion 521 of the conductive layer 52.

In such a semiconductor memory device 1, for example, defect analysis such as OBIRCH analysis for detecting a structural defect inside the semiconductor memory device 1 by emitting laser from the upper surface 500 shown in FIG. 3 toward the inside is sometimes performed. In such defect analysis, the contact portions 521 that are disposed regularly in the conductive layer 52 of the upper cell chip 50 are used as a mark for analysis of the semiconductor memory device 1. If the contact portions 521 are used as a mark, it is possible to perform the defect analysis of the upper cell chip 50 as appropriate. However, in the lower cell chip 40, there is no distinct mark like the contact portion 521. This causes difficulty in the defect analysis of the lower cell chip 40.

From this point, in the semiconductor memory device 1 of the embodiment, as described above, because the simulated shape portion 60 having a shape similar to the contact portion 521 of the conductive layer 52 is formed in the conductive layer 42 of the lower cell chip 40, it is possible to use the simulated shape portion 60 as a mark in performing the defect analysis. As a result, it is possible to improve the accuracy of the defect analysis of the lower cell chip 40.

In the semiconductor memory device 1 of the embodiment, the wires 420a to 420c and the bridging wires 421a to 421c are provided in the conductive layer 42 of the lower cell chip 40. The wires 420a to 420c extend in the X direction and are disposed at the intervals in the Y direction. The bridging wires 421a to 421c couple the wires 420a to 420c in the Y direction and are disposed at the intervals in the X direction. The simulated shape portion 60 includes a portion of a combination of the wires 420a to 420c and the bridging wires 421a to 421c.

According to the configuration, it is possible to form a gap between the wires 420a to 420c and between the bridging wires 421a to 421c. With this, because it is possible to make the aperture ratio of the lower cell chip 40 close to the aperture ratio of the upper cell chip 50, laser can easily reach the inside of the semiconductor memory device 1 while performing defect analysis such as OBIRCH analysis. For this reason, it is possible to perform defect analysis with higher accuracy.

The bonding pads PD44d of the conductive layer 43 and the bonding pads PD34 of the upper cell chip 50 that are joined to the bonding pads PD44d are joined to each other and function as dummy pads. According to the configuration, compared to a structure in which there are no such dummy pads, it is possible to prevent the misalignment of the lower cell chip 40 and the upper cell chip 50.

The bonding pads PD44 of the lower cell chip 40 and the bonding pads PD34 of the upper cell chip 50 are disposed in a honeycomb shape when viewed from the Z direction. According to the configuration, it is possible to dispose the bonding pads PD44 and the bonding pads PD34 of the upper cell chip 50 with higher density. With this, it is possible to achieve a reduction in the size of the semiconductor memory device 1.

### 1.5 First Modification Example

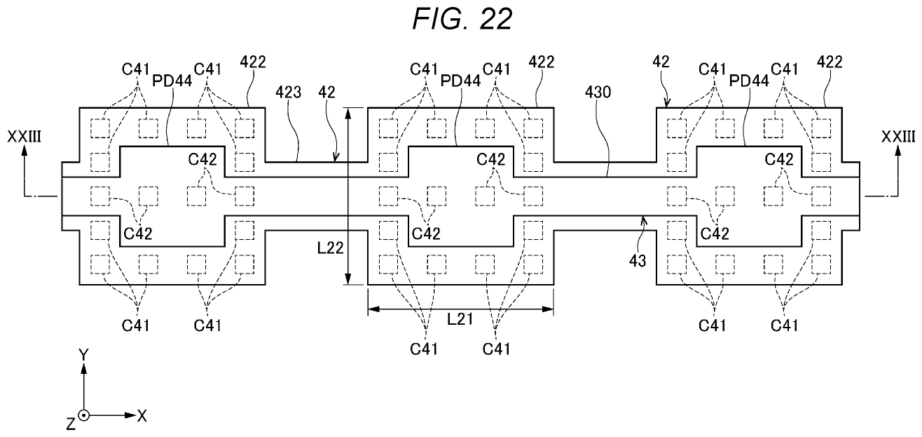

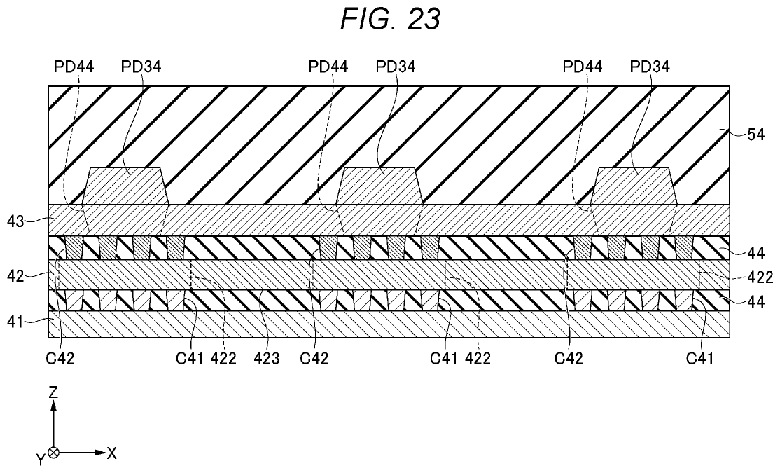

FIG. 22 shows a plan-view structure of the periphery of conductive layers 42 and 43 of a lower cell chip 40 of the modification example. FIG. 23 shows a cross-sectional view taken along the line XXIII-XXIII of FIG. 22. In FIG. 22, the insulating layer 44 is not shown.

As shown in FIGS. 22 and 23, the conductive layer 42 of the modification example includes a plurality of simulated shape portions 422 that are disposed at predetermined intervals in the X direction, and a wire 423 that connects the plurality of simulated shape portions 422 in the X direction. The simulated shape portion 422 is formed in a rectangular shape when viewed from the X direction and has a shape similar to the contact portion 521 of the conductive layer 52 of the upper cell chip 50. Lengths L21 and L22 of the simulated shape portion 422 in the X direction and the Y direction are set to, for example, 3 μm. A plurality of contact plugs C41 are joined to a bottom surface of the simulated shape portion 422 at predetermined intervals along an outer circumference. The simulated shape portion 422 is electrically connected to the source layer 41 via the contact plugs C41.

The bonding pad PD44 is disposed above the simulated shape portion 422 of the conductive layer 42. The wire 430 of the conductive layer 43 is disposed above the wire 423 of the conductive layer 42. The simulated shape portion 422 and the bonding pad PD44, and the wire 423 of the conductive layer 42 and the wire 430 of the conductive layer 43 are electrically connected via the contact plugs C42 that are disposed at the predetermined intervals in the X direction.

If a structure as the modification example is used, it is possible to implement the simulated shape portion 422 with a simpler structure.

### 1.6 Second Modification Example

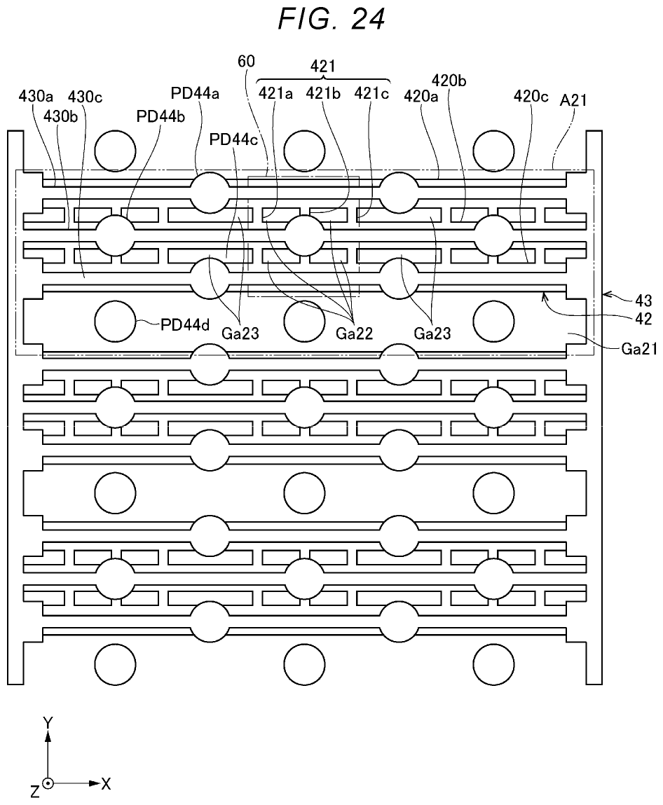

As shown in FIG. 24, bonding pads PD44 may be formed in a columnar shape. The same applies to other bonding pads.

### 2 Second Embodiment

Next, a second embodiment of a semiconductor memory device 1 will be described. Hereinafter, description will be made focusing on a difference from the semiconductor memory device 1 of the first embodiment.

### 2.1 Structure of Semiconductor Memory Device 1

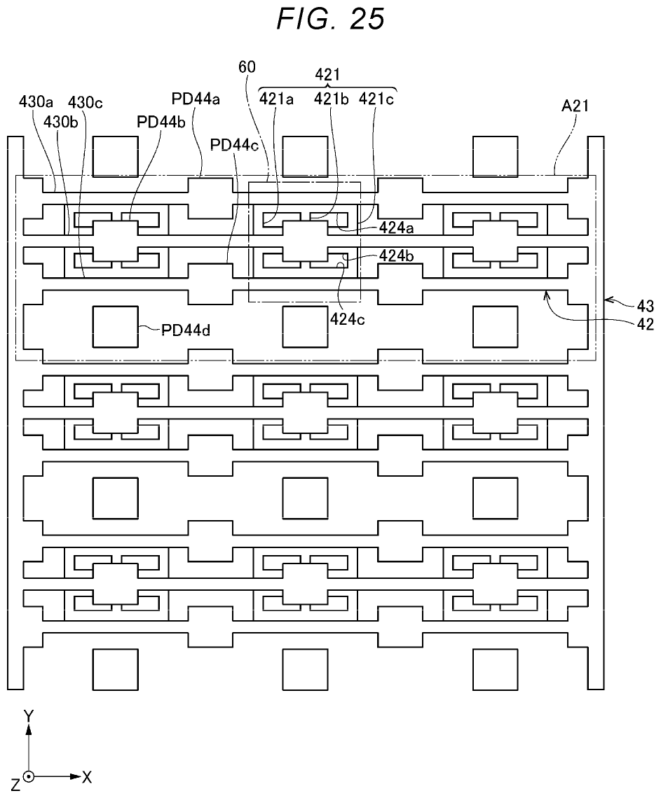

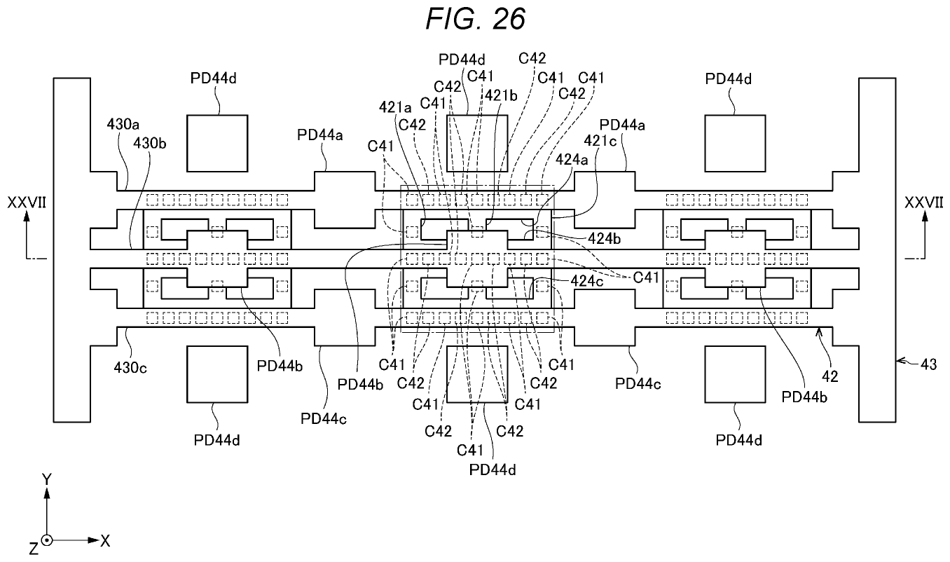

As shown in FIGS. 25 and 26, a conductive layer 42 of the embodiment is different from the conductive layer 42 shown in FIG. 8 in that bridging wires 424a to 424c are provided instead of the wires 420a to 420c. The bridging wire 424a couples one end portion of the respective bridging wires 421a to 421c in the Y direction. The bridging wire 424c couples the other end portion of the respective bridging wires 421a and 421c in the Y direction. The bridging wire 424b couples portions positioned between the bridging wires 424a and 424c in the Y direction. With such a structure, a rectangular frame is formed by the bridging wires 424a and 424c and the bridging wires 421a and 421c, and the bridging wire 424b and the bridging wire 421b are disposed in a cross shape in the rectangular frame. In the embodiment, a simulated shape portion 60 is formed by the bridging wires 421a to 421c and the bridging wires 424a to 424c. Lengths of the simulated shape portion 60 in the X direction and the Y direction are set to, for example, 3 μm.

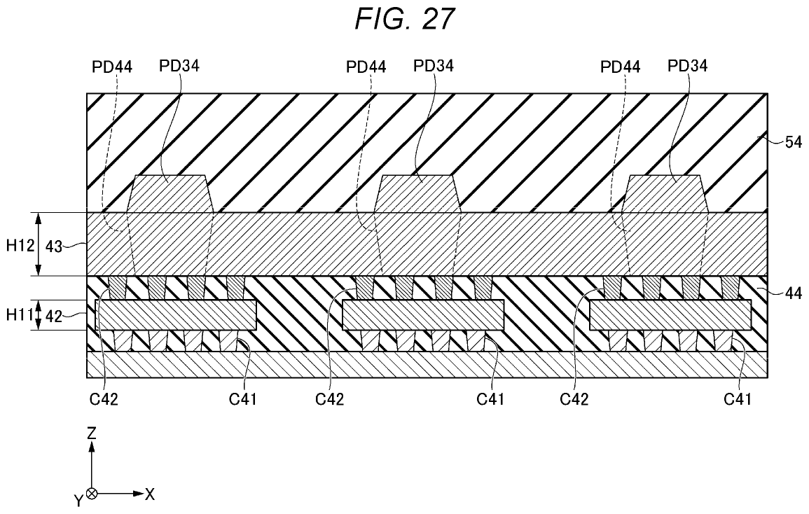

FIG. 27 shows a cross-sectional structure taken along the line XXVII-XXVII of FIG. 26. As shown in FIG. 27, in the semiconductor memory device 1 of the embodiment, the thickness H11 of the conductive layer 42 in the Z direction is set to 690 nm, and the thickness H12 of the conductive layer 43 in the Z direction is set to 1000 nm. That is, the conductive layer 43 is increased in thickness with respect to the semiconductor memory device 1 of the first embodiment.

### 2.2 Functions and Effects

In this way, the conductive layer 42 of the embodiment is different from the conductive layer 42 of the first embodiment shown in FIG. 8 in that portions configuring the simulated shape portion 60 are not connected via wires. That is, the conductive layer 42 has a shape in which a plurality of bridging wires 421a to 421c and bridging wires 424a to 424c that form the simulated shape portion 60 are independently disposed. According to such a structure of the lower cell chip 40, it is possible to increase the aperture ratio compared to the lower cell chip 40 of the first embodiment by not providing the wires 420a to 420c. Specifically, in the lower cell chip 40 of the embodiment, an aperture ratio of a region A21 surrounded by a two-dot chain line shown in FIG. 25 is 45% to 55%.

Because it is possible to more accurately reproduce the shape of the contact portion 521 of the conductive layer 52 by the bridging wires 421a to 421c and the bridging wires 424a to 424c, it is possible to further improve the accuracy of the defect analysis of the lower cell chip 40.

### 2.3 Modification Example

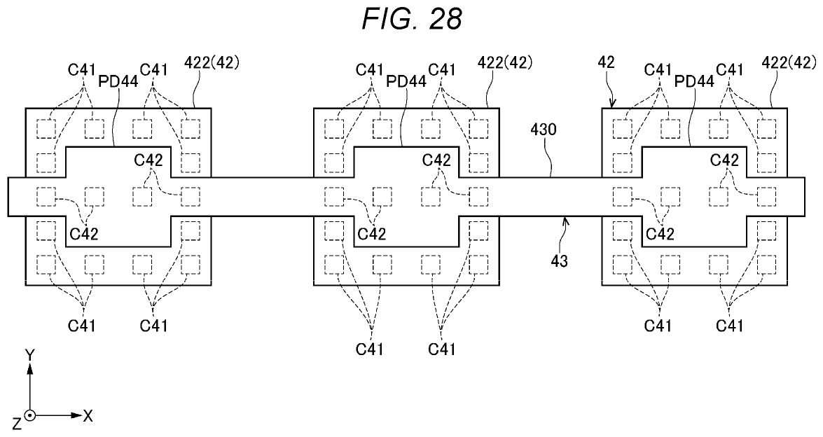

FIG. 28 shows a plan-view structure of the periphery of conductive layers 42 and 43 of a lower cell chip 40 of the modification example. As shown in FIG. 28, while the conductive layers 42 and 43 of the modification example are different from the conductive layers 42 and 43 shown in FIG. 22 in that the wire 423 is not provided, other points are the same. According to such a structure, it is possible to implement a structure in which the simulated shape portions 60 are not connected via a wire.

### 3 Third Embodiment

Next, a third embodiment of a semiconductor memory device 1 will be described. Hereinafter, description will be made focusing on a difference from the semiconductor memory device 1 of the first embodiment.

### 3.1 Structure of Semiconductor Memory Device 1

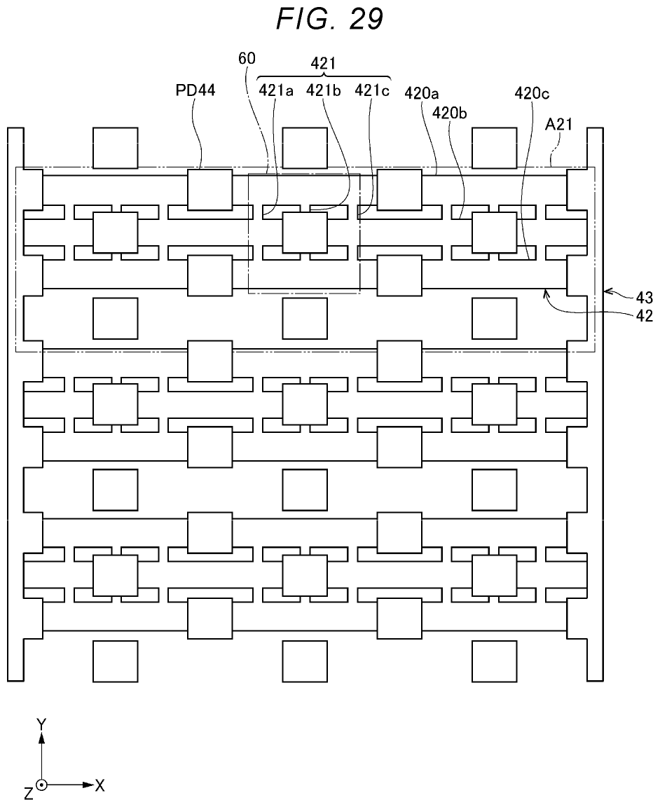

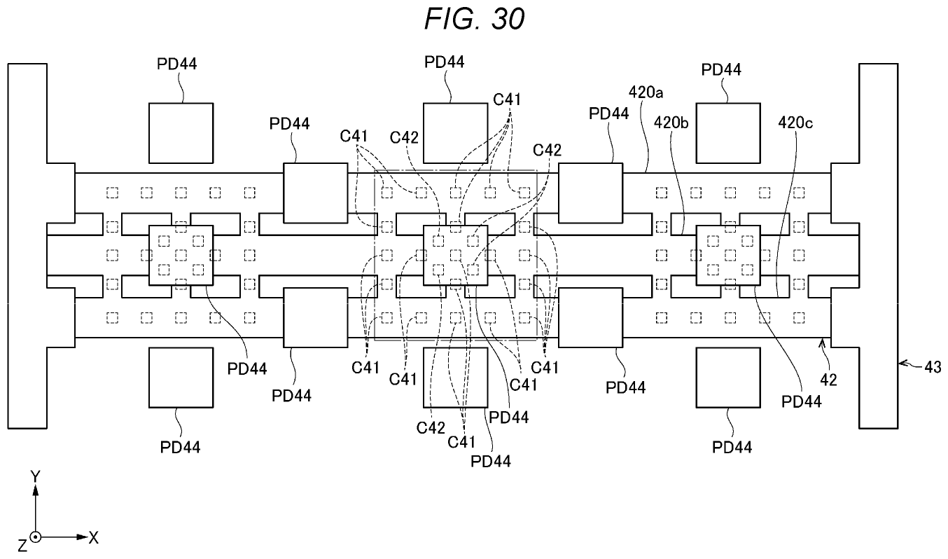

As shown in FIGS. 29 and 30, a conductive layer 43 of the embodiment is different from the conductive layer 43 shown in FIG. 8 in that the wires 430a to 430c are not provided. As shown in FIG. 30, of a plurality of bonding pads PD44, the bottom surface of the bonding pad PD44 provided above a wire 420b of the conductive layer 43 is electrically connected to the wire 420b of the conductive layer 43 through the contact plugs C42.

### 3.2 Functions and Effects

The lower cell chip 40 includes the conductive layer 43 that is provided between a plurality of bonding pads PD44 and the conductive layer 41, the contact plugs C41 that electrically connect the conductive layer 41 and the conductive layer 42, and the contact plugs C42 that electrically connect the plurality of bonding pads PD44 and the conductive layer 43.

According to the configuration, it is possible to increase the aperture ratio compared to the lower cell chip 40 of the first embodiment by not providing the wires 430a to 430c. Specifically, in the lower cell chip 40 of the embodiment, an aperture ratio of a region A21 surrounded by a two-dot chain line shown in FIG. 29 is 45% to 55%.

Because it is possible to change the shape or disposition of the bonding pads PD44 as long as the wires 430a to 430c are not provided in the conductive layer 43, it is possible to improve a degree of freedom of design.

### 3.3 Modification Example

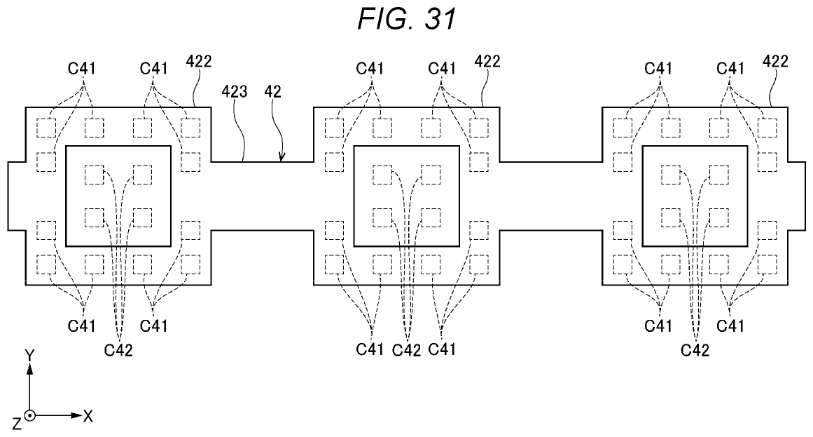

FIG. 31 shows a plan-view structure of the periphery of conductive layers 42 and 43 of a lower cell chip 40 of the modification example. As shown in FIG. 31, the conductive layers 42 and 43 of the modification example are different from the conductive layer 43 shown in FIG. 28 in that the wire 430 is not provided and the contact plugs C42 are provided only on the bottom surface of the bonding pad PD44, but other points are the same. Also with such a structure, it is possible to obtain functions and effects same as or similar to the semiconductor memory device 1 of the third embodiment.

### 4 Fourth Embodiment

Next, a fourth embodiment of a semiconductor memory device 1 will be described. Hereinafter, description will be made focusing on a difference from the semiconductor memory device 1 of the first embodiment.

### 4.1 Structure of Semiconductor Memory Device 1

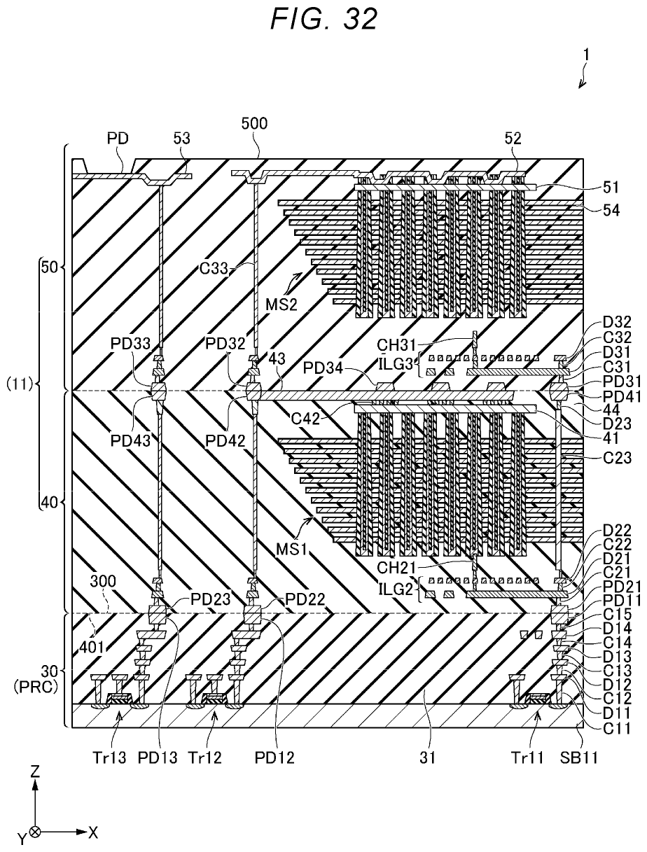

As shown in FIG. 32, the semiconductor memory device 1 of the embodiment is different from the semiconductor memory device 1 of the first embodiment shown in FIG. 3 in that the conductive layer 42 is not provided.

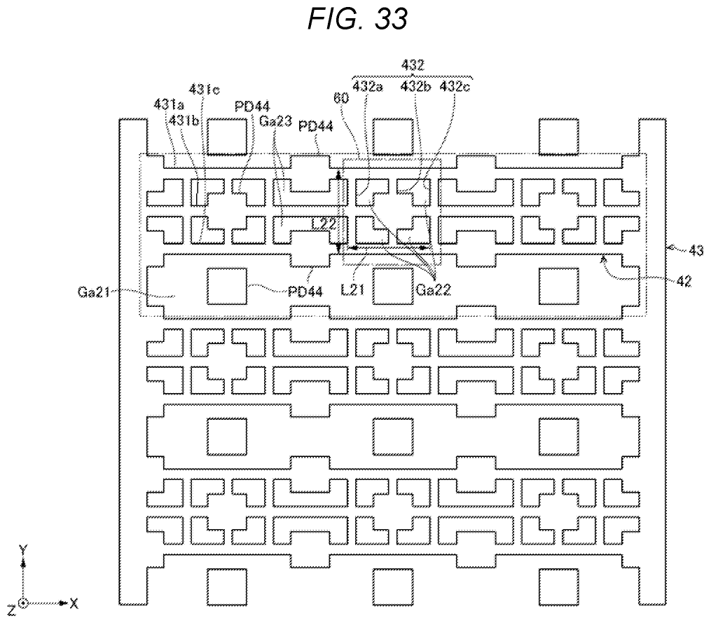

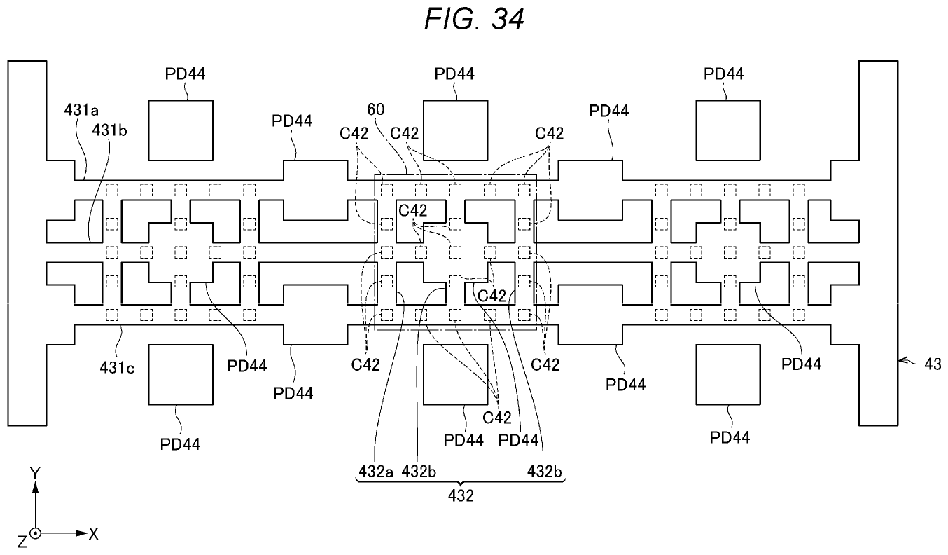

Specifically, as shown in FIGS. 33 and 34, in the lower cell chip 40, the bottom surface of the conductive layer 43 is electrically connected to the conductive layer 41 via the contact plugs C42.

As shown in FIG. 33, the conductive layer 43 of the embodiment has a structure similar to the conductive layer 42 of the first embodiment shown in FIG. 8. That is, in the conductive layer 43, with three wires 431a to 431c extending in the X direction as a set, a plurality of sets of wires 431a to 431c are disposed in parallel at predetermined gap Ga21 in the Y direction. Each of the wires 431a to 431c passes through the bonding pads PD44 disposed in a line in the X direction.

In the conductive layer 43, a plurality of bridging portions 432 pass through the wires 431a to 431c in the Y direction. Each bridging portion 432 includes bridging wires 432a to 432c that are disposed at gaps Ga22 in the X direction. The three bridging portions 432 including the three bridging wires 432a to 432c are disposed in parallel in the X direction at gaps Ga23 greater than the gap Ga22.

A portion in the conductive layer 43 where one bridging portion 432 is provided, that is, a portion indicated by a one-dot chain line in FIG. 33 forms a rectangular simulated shape portion 60 similar to the shape of the contact portion 521 of the conductive layer 52 shown in FIG. 4. Lengths L21 and L22 of the simulated shape portion 60 in the X direction and the Y direction are set to, for example, 3 μm.

As shown in FIG. 34, the contact plugs C42 are disposed at predetermined intervals in the X direction in a portion in the region of the simulated shape portion 60 in each of the wires 431a to 431c. The contact plugs C42 are disposed at predetermined intervals in the Y direction with respect to each of the bridging wires 432a to 432c.

### 4.2 Functions and Effects

As described above, the lower cell chip 40 of the embodiment includes the contact plugs C42 that electrically connect the conductive layer 41 and the conductive layer 43. With this structure, because it is possible to omit the conductive layer 42 and the contact plugs C41 compared to the semiconductor memory device 1 of the first embodiment shown in FIG. 3, it is possible to simplify the structure.

### 4.3 Modification Example

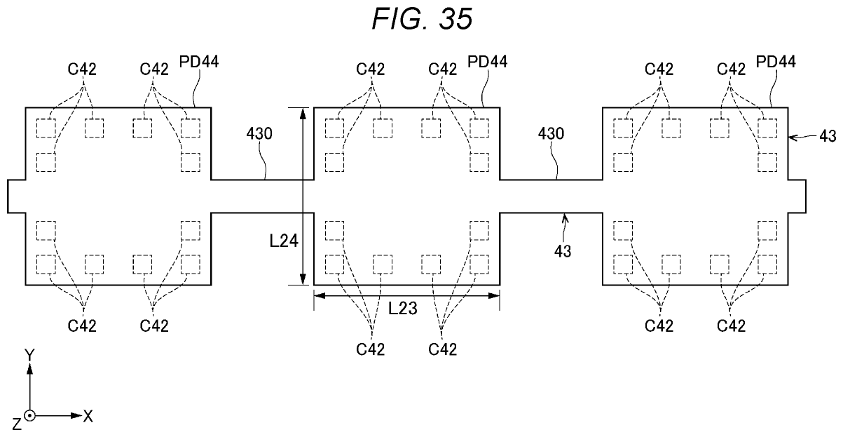

FIG. 35 shows a plan-view structure of the periphery of a conductive layer 43 of a lower cell chip 40 of the modification example. As shown in FIG. 35, in the conductive layer 43 of the embodiment, the conductive layer 42 is not provided compared to the conductive layers 42 and 43 shown in FIG. 22. The bonding pad PD44 has the same size as the simulated shape portion 422 shown in FIG. 22. That is, lengths of the bonding pad PD44 in the X direction and the Y direction are set to, for example, 3 μm. With this, in the modification example, the bonding pad PD44 forms a simulated shape portion. Also with such a structure, it is possible to obtain functions and effects same as or similar to the semiconductor memory device 1 of the fourth embodiment.

### 5 Fifth Embodiment

Next, a fifth embodiment of a semiconductor memory device 1 will be described. Hereinafter, description will be made focusing on a difference from the semiconductor memory device 1 of the first embodiment.

### 5.1 Structure of Semiconductor Memory Device 1

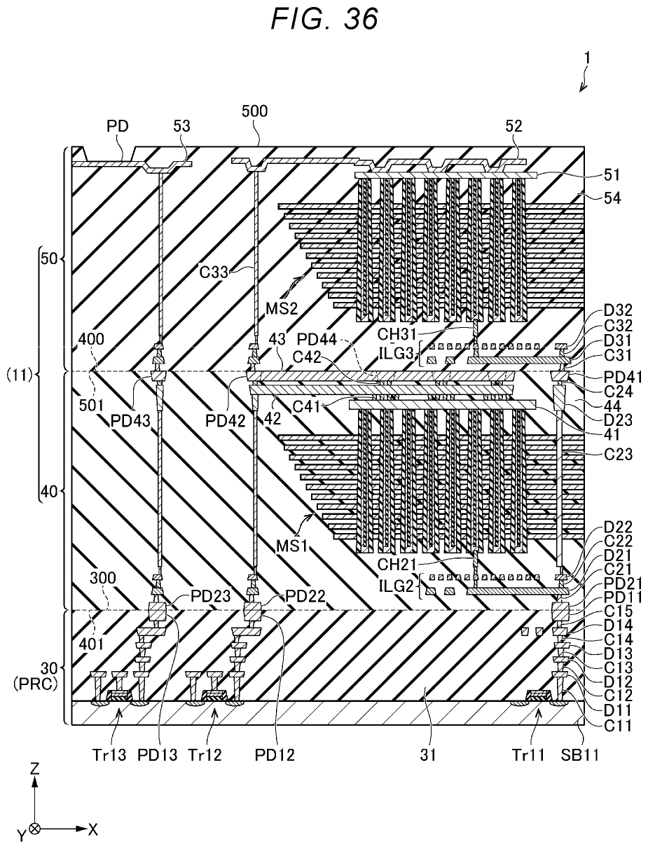

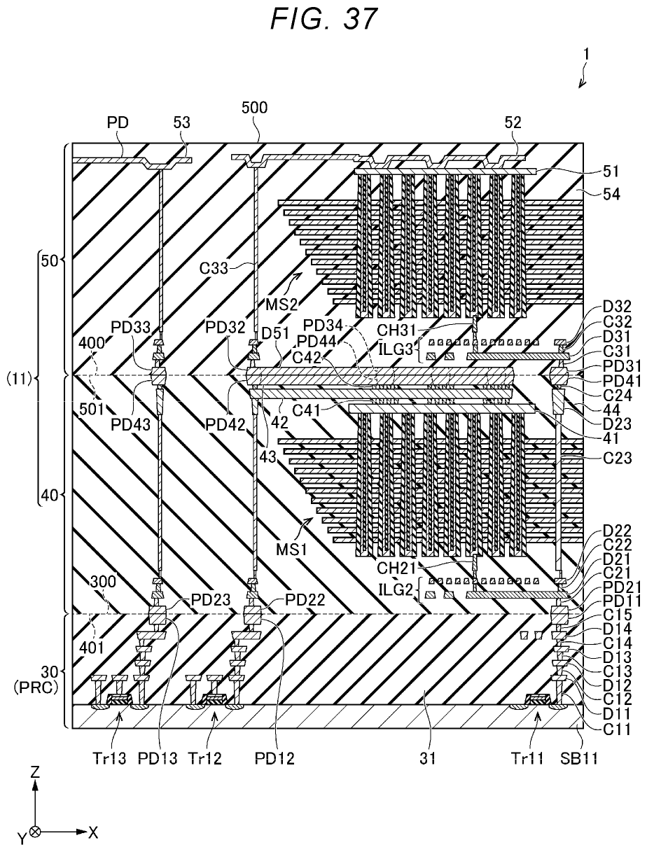

As shown in FIG. 36, the semiconductor memory device 1 of the embodiment is different from the semiconductor memory device 1 of the first embodiment shown in FIG. 3 in that the bonding pads PD31, PD32, PD33, and PD34 are not provided in the upper cell chip 50. In the semiconductor memory device 1 of the embodiment, the contact plugs C31 of the upper cell chip 50 are joined to the bonding pads PD41, PD42, and PD43 of the lower cell chip 40.

### 5.2 Functions and Effects

Also with the structure as the semiconductor memory device 1 of the embodiment, it is possible to obtain functions and effects same as or similar to the semiconductor memory device 1 of the first embodiment.

### 6 Sixth Embodiment

Next, a sixth embodiment of the semiconductor memory device 1 will be described. Hereinafter, description will be made focusing on a difference from the semiconductor memory device 1 of the first embodiment.

### 6.1 Structure of Semiconductor Memory Device 1

As shown in FIG. 37, in the semiconductor memory device 1 of the embodiment, in comparison with the semiconductor memory device 1 of the first embodiment shown in FIG. 3, a conductive layer D51 is further formed in the upper cell chip 50 to couple a plurality of bonding pads PD34 in the X direction. An end portion of the conductive layer D51 is electrically connected to the bonding pad PD32.

### 6.2 Functions and Effects

Also in the structure of the semiconductor memory device 1 of the embodiment, functions and effects same as or similar to those in the semiconductor memory device 1 of the first embodiment can be obtained.

### 7 Other Embodiments

The present disclosure is not limited to the above-described specific example. For example, the semiconductor memory device 1 is not limited to a structure in which two cell chips are stacked, and may have a structure in which three or more cell chips are stacked.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a substrate;
a first cell chip that is provided on a first direction side of the substrate; and
a second cell chip that is provided between the first cell chip and the substrate and is bonded to the first cell chip,
wherein the first cell chip includes
a first stack including a plurality of first memory cell transistors,
a first conductive layer that is provided on the first direction side of the first stack and is used as a first source line,
a second conductive layer that is provided on the first direction side of the first conductive layer and is electrically connected to the first conductive layer, and
a plurality of first bonding pads that are provided on a first surface of the first cell chip at which the first cell chip is bonded to the second cell chip, and
the second cell chip includes
a second stack including a plurality of second memory cell transistors,
a third conductive layer that is provided on the first direction side of the second stack and is used as a second source line,
a plurality of second bonding pads that are disposed on a second surface of the second cell chip at which the second cell chip is bonded to the first cell chip, and are joined to the plurality of first bonding pads, respectively, and
a fourth conductive layer that extends in a second direction intersecting the first direction, electrically couples the plurality of second bonding pads, and is electrically connected to the third conductive layer, and
wherein the second conductive layer and the fourth conductive layer are electrically connected.

2. The semiconductor memory device according to claim 1,
wherein the second conductive layer and the fourth conductive layer contain conductive materials different from each other.

3. The semiconductor memory device according to claim 2,
wherein the second conductive layer contains aluminum, and
the fourth conductive layer contains copper.

4. The semiconductor memory device according to claim 1,
wherein the plurality of first bonding pads and the plurality of second bonding pads are disposed in a honeycomb shape when viewed from the first direction.

5. The semiconductor memory device according to claim 1, wherein the second cell chip further includes
a fifth conductive layer that is provided between the third conductive layer and the fourth conductive layer,
a first contact that electrically connects the third conductive layer and the fifth conductive layer, and
a second contact that electrically connects the fourth conductive layer and the fifth conductive layer.

6. The semiconductor memory device according to claim 5, wherein a thickness of the fourth conductive layer is about equal to a thickness of the fifth conductive layer.

7. The semiconductor memory device according to claim 5, wherein a thickness of the fourth conductive layer is greater than a thickness of the fifth conductive layer.

8. The semiconductor memory device according to claim 5, wherein the fifth conductive layer includes
a plurality of first wires that extend in the second direction and are disposed at intervals in a third direction intersecting both the first direction and the second direction, and
a plurality of second wires that electrically couple the plurality of first wires in the third direction and are disposed at intervals in the second direction.

9. The semiconductor memory device according to claim 1,
wherein the second cell chip further includes a first contact that electrically connects the third conductive layer and the fourth conductive layer.

10. The semiconductor memory device according to claim 1, wherein
the first cell chip further includes a sixth conductive layer that extends in the second direction along the first surface and electrically couples the plurality of first bonding pads, and
the sixth conductive layer is electrically connected to the second conductive layer and the fourth conductive layer.

11. The semiconductor memory device according to claim 1, wherein an aperture ratio of the second cell chip is about the same as an aperture ratio of the first cell chip.

12. The semiconductor memory device according to claim 1, wherein an aperture ratio of the second cell chip is greater than an aperture ratio of the first cell chip.

13. A semiconductor memory device comprising:
a substrate;
a first cell chip that is provided on a first direction side of the substrate; and
a second cell chip that is provided between the first cell chip and the substrate and is bonded to the first cell chip,
wherein the first cell chip includes
a first stack including a plurality of first memory cell transistors,
a first conductive layer that is provided on the first direction side of the first stack and is used as a first source line,
a second conductive layer that is provided on the first direction side of the first conductive layer and is electrically connected to the first conductive layer, and
a plurality of first bonding pads that are provided on a first surface of the first cell chip at which the first cell chip is bonded to the second cell chip, and
the second cell chip includes a second stack including a plurality of second memory cell transistors,
a third conductive layer that is provided on the first direction side of the second stack and is used as a second source line,
a plurality of second bonding pads that are disposed on a second surface of the second cell chip at which the second cell chip is bonded to the first cell chip, and are joined to the plurality of first bonding pads, respectively,
a fourth conductive layer that is provided between the plurality of second bonding pads and the third conductive layer and extends in a second direction intersecting the first direction,
a first contact that electrically connects the third conductive layer and the fourth conductive layer, and
a second contact that electrically connects the plurality of second bonding pads and the fourth conductive layer, and
wherein the second conductive layer and the fourth conductive layer are electrically connected.

14. The semiconductor memory device according to claim 13,
wherein the second conductive layer and the fourth conductive layer contain conductive materials different from each other.

15. The semiconductor memory device according to claim 14,
wherein the second conductive layer contains aluminum, and
the fourth conductive layer contains copper.

16. The semiconductor memory device according to claim 13, wherein
the second cell chip further includes a fifth conductive layer that electrically couples the second bonding pads, and
a thickness of the fifth conductive layer is greater than a thickness of the fourth conductive layer.

17. The semiconductor memory device according to claim 13, wherein an aperture ratio of the second cell chip is greater than an aperture ratio of the first cell chip.

18. A semiconductor memory device comprising:
a substrate;
a first cell chip that is provided on a first direction side of the substrate; and
a second cell chip that is provided between the first cell chip and the substrate and is bonded to the first cell chip,
wherein the first cell chip includes
a first stack including a plurality of first memory cell transistors,
a first conductive layer that is provided on the first direction side of the first stack and is used as a first source line, and
a second conductive layer that is provided on the first direction side of the first conductive layer and is electrically connected to the first conductive layer, and
the second cell chip includes
a second stack including a plurality of second memory cell transistors,
a third conductive layer that is provided on the first direction side of the second stack and is used as a second source line,
a plurality of bonding pads that are disposed on a second surface of the second cell chip that is bonded to the first cell chip,
a fourth conductive layer that extends in a second direction intersecting the first direction and electrically couples the plurality of bonding pads,
a fifth conductive layer that is provided between the third conductive layer and the fourth conductive layer,
a first contact that electrically connects the third conductive layer and the fifth conductive layer, and
a second contact that electrically connects the fourth conductive layer and the fifth conductive layer, and
wherein the second conductive layer, the third conductive layer, the fourth conductive layer, and the fifth conductive layer are electrically connected.

19. The semiconductor memory device according to claim 18,
wherein the second conductive layer and the fourth conductive layer contain conductive materials different from each other.

20. The semiconductor memory device according to claim 19,
wherein the second conductive layer contains aluminum, and
the fourth conductive layer contains copper.
